(19) United States
(12) Patent Application Publication
(10) Pub. No.: US 2018/0069537 A1
(43) Pub. Date: Mar. 8, 2018

(54) LEVEL SHIFT CIRCUIT AND SEMICONDUCTOR DEVICE

(71) Applicant: Renesas Electronics Corporation, Tokyo (JP)

(72) Inventor: Dai KAMIMARU, Tokyo (JP)

(21) Appl. No.: 15/626,143

(22) Filed: Jun. 18, 2017

(30) Foreign Application Priority Data
Sep. 7, 2016 (JP) 2016-174272

(51) Int. Cl. H03K 3/356

(52) U.S. Cl. CPC H03K 3/356113; H03K 3/356182; H03K 3/356165

(57) ABSTRACT

The present invention provides a level shift circuit and a semiconductor device capable of extending a power supply potential range in which the level shift operation can be performed.

A level shift circuit includes amplitude amplifying circuits AMPt1, AMPb1, and a sublevel shift circuit SLSC1. The amplitude amplifying circuits AMPt1, AMPb1 are supplied with a reference power supply potential GND and an external power supply potential VDD2 and, in response to an input signal (INT, INB) of an internal power supply voltage amplitude (VDD1 (<VDD2) amplitude), output signals SND1, SND2 with an amplitude larger than the VDD1 amplitude and smaller than the external power supply voltage amplitude (VDD2 amplitude). The sublevel shift circuit SLSC1 is supplied with the reference power supply potential GND and the external power supply potential VDD2, and outputs an output signal (OUT, OUTB) of the VDD2 amplitude in response to the signals SND1, SND2.

### CROSS-REFERENCE TO RELATED APPLICATIONS

The disclosure of Japanese Patent Application No. 2016-174272 filed on Sep. 7, 2016 including the specification, drawings and abstract is incorporated herein by reference in its entirety.

### BACKGROUND

The present invention relates to a level shift circuit and a semiconductor device, and specifically to, for example, a level shift circuit that converts a voltage amplitude from a smaller amplitude to a larger amplitude, and a semiconductor device including the same.

For example, Japanese Unexamined Patent Application Publication No. HEI07 (2019)-154217 discloses a level converter for substantially equalizing a fall time and a rise time of a signal. This level converter includes a basic circuit comprised of a pair of pMOS transistors and a pair of nMOS transistors, and an additional circuit coupled in parallel with the nMOS transistors. The additional circuit includes an nMOS transistor and a switch element for selecting a parallel-coupled state or a parallel-uncoupled state of the nMOS transistor.

### SUMMARY

The transistor used in the semiconductor is becoming finer year by year, and especially a thin film transistor used inside the device is scaled taking into account the performance and the power density. With miniaturization and reduction of the power consumption in the process, the power supply potential (referred to as an internal power supply potential herein) of the thin film transistor (i.e., internal transistor) lowers. On the other hand, for example, the power supply potential (referred to as an external power supply potential herein) of a thick film transistor (i.e., external transistor) for use as an interface with outside is generally constrained by the standard of interface between devices, which remains constant regardless of the miniaturization. Consequently, the difference between the internal power supply potential and the external power supply potential tends to increase every year.

The semiconductor device is provided with, for example, the level shift circuit as disclosed in Japanese Unexamined Patent Application Publication No. HEI07 (2019)-154217 to convert a signal having an amplitude level of such am internal power supply potential into a signal having an amplitude level of the external power supply potential. However, as the difference between the internal power supply potential and the external power supply potential increases, it may become difficult for such a level shift circuit to perform a level shift operation while satisfying a predetermined performance. As a result, there is a risk of reducing a power supply potential range in which the level shift operation can be performed.

Embodiments described later are made in the light of above issues, and other problems and novel features will be apparent from the description herein and accompanying drawings.

A level shift circuit according to one embodiment receives an input signal having a first power supply voltage amplitude that transits between a reference power supply potential and a first power supply potential higher than the reference power supply potential, and outputs to an output node an output signal having a second power supply voltage amplitude that transits between the reference power supply potential and a second power supply potential higher than the first power supply potential. The level shift circuit includes an amplitude amplifying circuit and a sublevel shift circuit. The amplitude amplifying circuit is supplied with the reference power supply potential and the second power supply potential, and outputs a first signal having a first amplitude larger than the first power supply voltage amplitude and smaller than the second power supply voltage amplitude. The sublevel shift circuit is supplied with the reference power supply potential and the second power supply potential, and in response to the first signal having the first amplitude, outputs the output signal having the second power supply voltage amplitude.

According to the one embodiment, it is possible to extend the power supply potential range in which the level shift operation can be performed.

### BRIEF DESCRIPTION OF THE DRAWINGS

FIG. 1 is a schematic diagram showing an exemplary configuration of a semiconductor device according to a first embodiment of the present invention;

FIG. 2A is a circuit diagram showing an exemplary configuration of a level shift circuit according to the first embodiment of the invention;

FIG. 2B is a circuit diagram showing an exemplary state of each node and each transistor in a steady state in FIG. 2A;

FIG. 2C is a circuit diagram showing an example of a state transition of each node and each transistor during a transition period in FIG. 2A;

FIG. 2D is a transition diagram summarizing one example of a time-series state transition of each node and each transistor associated with transition of an input signal in FIG. 2A;

FIG. 2E is a transition diagram summarizing one example of a time-series state transition of each node and each transistor associated with the transition of the input signal in a direction opposite from FIG. 2D;

FIG. 3A is a circuit diagram showing an exemplary configuration of a level shift circuit according to a second embodiment of the invention;

FIG. 3B is a circuit diagram showing an exemplary state of each node and each transistor in the steady state in FIG. 3A;

FIG. 3C is a transition diagram summarizing one example of a time-series state transition of each node and each transistor associated with transition of an input signal in FIG. 3A;

FIG. 3D is a transition diagram summarizing one example of a time-series state transition of each node and each transistor associated with the transition of the input signal in a direction opposite from FIG. 3C;

FIG. 4A is a circuit diagram showing an exemplary configuration of a level shift circuit according to a third embodiment of the invention;

FIG. 4B is a circuit diagram showing an exemplary state of each node and each transistor in the steady state in FIG. 4A;

FIG. 4C is a circuit diagram showing one example of a state transition of each node and each transistor during a transition period in FIG. 4A;

FIG. 4D is a transition diagram summarizing one example of a time-series state transition of each node and each transistor associated with transition of an input signal in FIG. 4A;

FIG. 4E is a transition diagram summarizing one example of a time-series state transition of each node and each transistor associated with the transition of the input signal in a direction opposite from FIG. 4D;

FIG. 5A is a circuit diagram showing an exemplary configuration of a level shift circuit according to a fourth embodiment of the invention;

FIG. 5B is a circuit diagram showing an exemplary state of each node and each transistor in the steady state in FIG. 5A;

FIG. 5C is a transition diagram summarizing one example of a time-series state transition of each node and each transistor associated with transition of an input signal in FIG. 5A;

FIG. 5D is a transition diagram summarizing one example of a time-series state transition of each node and each transistor associated with the transition of the input signal in a direction opposite from FIG. 5C;

FIG. 6A is a circuit diagram showing an exemplary configuration of a level shift circuit according to a fifth embodiment of the invention;

FIG. 6B is a circuit diagram showing an exemplary state of each node and each transistor in a steady state in FIG. 6A;

FIG. 6C is a circuit diagram showing an example of a state transition of each node and each transistor during a transition period in FIG. 6A;

FIG. 6D is a circuit diagram showing an example of a state transition of each node and each transistor following FIG. 6C;

FIG. 6E is a transition diagram summarizing one example of a time-series state transition of each node and each transistor associated with transition of an input signal in FIG. 6A;

FIG. 6F is a transition diagram summarizing one example of a time-series state transition of each node and each transistor associated with the transition of the input signal in a direction opposite from FIG. 6E;

FIG. 7A is a circuit diagram showing an exemplary configuration of a level shift circuit according to a sixth embodiment of the invention;

FIG. 7B is a circuit diagram showing an exemplary state of each node and each transistor in the steady state in FIG. 7A;

FIG. 7C is a circuit diagram showing an example of a state transition of each node and each transistor during a transition period in FIG. 7A;

FIG. 7D is a transition diagram summarizing one example of a time-series state transition of each node and each transistor associated with transition of an input signal in FIG. 7A;

FIG. 7E is a transition diagram summarizing one example of a time-series state transition of each node and each transistor associated with the transition of the input signal in a direction opposite from FIG. 7D;

FIG. 8A is a circuit diagram showing an exemplary configuration of a level shift circuit according to a seventh embodiment of the invention;

FIG. 8B is a circuit diagram showing an exemplary state of each node and each transistor in the steady state in FIG. 8A;

FIG. 8C is a circuit diagram showing an example of a state transition of each node and each transistor during a transition period in FIG. 8A;

FIG. 8D is a transition diagram summarizing one example of a time-series state transition of each node and each transistor associated with transition of an input signal in FIG. 8A;

FIG. 8E is a transition diagram summarizing one example of a time-series state transition of each node and each transistor associated with the transition of the input signal in a direction opposite from FIG. 8D;

FIG. 9 is a circuit diagram showing an exemplary configuration and an exemplary main operation of a level shift circuit used as a comparative example of the invention;

FIG. 10 is a diagram defining a potential of each signal and an operational state of each transistor used herein;

FIG. 11 is a diagram specifically illustrating one example of problems associated with the level shift circuit in FIG. 9; and

FIG. 12 is a circuit diagram showing a variation of the level shift circuit according to one embodiment of the invention.

### DETAILED DESCRIPTION

In the following embodiments, description will be given separately in a plurality of sections or embodiments for convenience and as needed, which are not unrelated to one another but one may be a variation, detailed description, supplementary explanation, or the like of part or all of others, unless otherwise stated. Furthermore, in the following embodiments, when referring to the number of elements or the like (including number, value, amount, range, and the like), it is not limited to the specific number but may be more or less than the specific number, unless otherwise stated or apparently limited to the specific number in principle.

Moreover, in the following embodiments, it is needless to say that the elements (including steps) are not necessarily essential unless otherwise stated or apparently considered to be necessary in principle. Similarly, in the following embodiments, when referring to the shape, positional relation, or the like of the elements, those substantially approximate to or similar to the shape or the like are included unless otherwise stated or apparently considered to be excluded in principle. The same applies to the numerical values and ranges.

Although not specifically limited, a circuit element configuring each functional block in the embodiments is formed over a semiconductor substrate such as monocrystalline silicon by the known integrated circuit technology such as CMOS (Complementary MOS). Although the embodiments employ a MOSFET (Metal Oxide Semiconductor Field Effect Transistor) (“MOS transistor” for short) as an example of a MISFET (Metal Insulator Semiconductor Field Effect Transistor), it is not intended to exclude a non-oxidized film as a gate insulation film.

Furthermore, in the embodiments, an n-channel type MOS transistor is referred to as an NMOS transistor, and a p-channel type MOS transistor is referred to as a PMOS transistor. Although coupling of substrate potentials of the MOS transistors is not described in the drawings, the coupling method is not limited as long as the MOS transistor can operate properly. Typically the substrate potentials of the NMOS transistor and the PMOS transistor are both coupled to the source potential.

Hereinbelow, embodiments of the invention will be described in detail with reference to the drawings. It should be noted that, in all the drawings for illustrating the embodiments, like parts are referred to by like numerals in principle, and the description thereof is not repeated.

### First Embodiment

### <<Configuration of Semiconductor Device>>

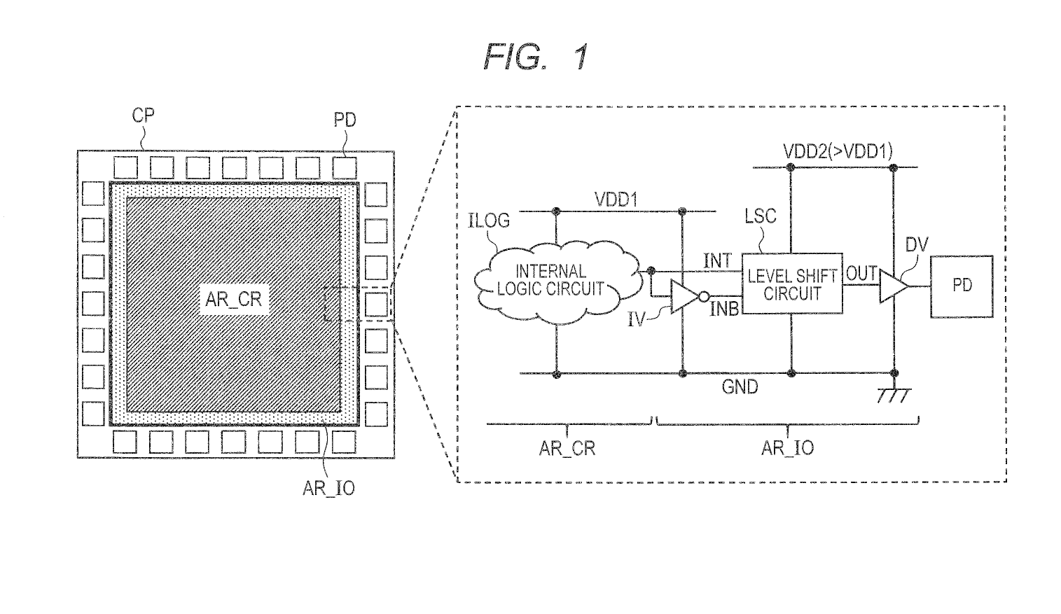

FIG. 1 is a schematic diagram showing an exemplary configuration of a semiconductor device according to a first embodiment of the present invention. FIG. 1 shows an exemplary layout configuration of the entire semiconductor device and an exemplary circuit formed in a partial region of the device. The semiconductor device shown in FIG. 1 includes a single semiconductor chip CP, which is typically a microcontroller (MCU: Micro Control Unit) or the like, though not specifically limited thereto. Arranged on a peripheral area of the semiconductor chip CP are a plurality of pads PD serving as coupling terminals to the outside of the chip. Provided inside the semiconductor chip CP is a core region AR_CR, and an IO (Input/Output) region AR_IO is arranged between the core region AR_CR and the pads PD.

Formed in the core region AR_CR is an internal logic circuit ILOG, represented by various registers such as, for example, a CPU (Central Processing Unit) and a GPIO (General Purpose Input/Output). The internal logic circuit ILOG is supplied with a reference power supply potential GND and an internal power supply potential VDD1 having a potential higher than that of the reference power supply potential GND. Formed on the IO region AR_IO are an inverter circuit IV, a level shift circuit LSC, and a driver circuit DV. The inverter circuit IV is supplied with the reference power supply potential GND and the internal power supply potential VDD1, and the level shift circuit LSC and the driver circuit DV are supplied with the reference power supply potential GND and an external power supply potential VDD2 having a potential higher than the internal power supply potential VDD1.

The internal logic circuit ILOG performs a predetermined processing, in which it outputs to an input node INT of the level shift circuit LSC an input signal (INT) of an internal power supply voltage amplitude (herein, “VDD1 amplitude” for short) that transitions between the reference power supply potential GND and the internal power supply potential VDD1. The inverter circuit IV outputs to an inverted input node INT of the level shift circuit LSC an inverted input signal (INB) having a polarity opposite from that of the input signal (INT).

The level shift circuit LSC converts the input signal (INT) or the inverted input signal (INB) of the VDD1 amplitude of the input node INT or the inverted input node INB into an output signal (OUT) of an external power supply voltage amplitude (herein, “VDD2 amplitude” for short) that transitions between the reference power supply potential GND and the external power supply potential VDD2, and outputs the resulting output signal (OUT) to an output node OUT. The driver circuit DV outputs the output signal (OUT) to a pad PD by predetermined driving ability.

Although not specifically limited, the internal power supply potential VDD1 is typically 1.2V or the like, and the external power supply potential VDD2 is 3.3 V, 5.0 V, or the like. However, the internal power supply voltage VDD1 is decreasing every year, for example, from 1.8 V to 1.2 V, to 1.0 V, and so on, along with the miniaturization and reduction of the power consumption in the process. On the other hand, the external power supply voltage VDD2 takes a fixed value based on a specification and a standard of an external interface such as, for example, a GPIO or an I₂C (Inter Integrated Circuit), regardless of the miniaturization.

### <<Configuration and Problem of Level Shift Circuit (Comparative Example)>>

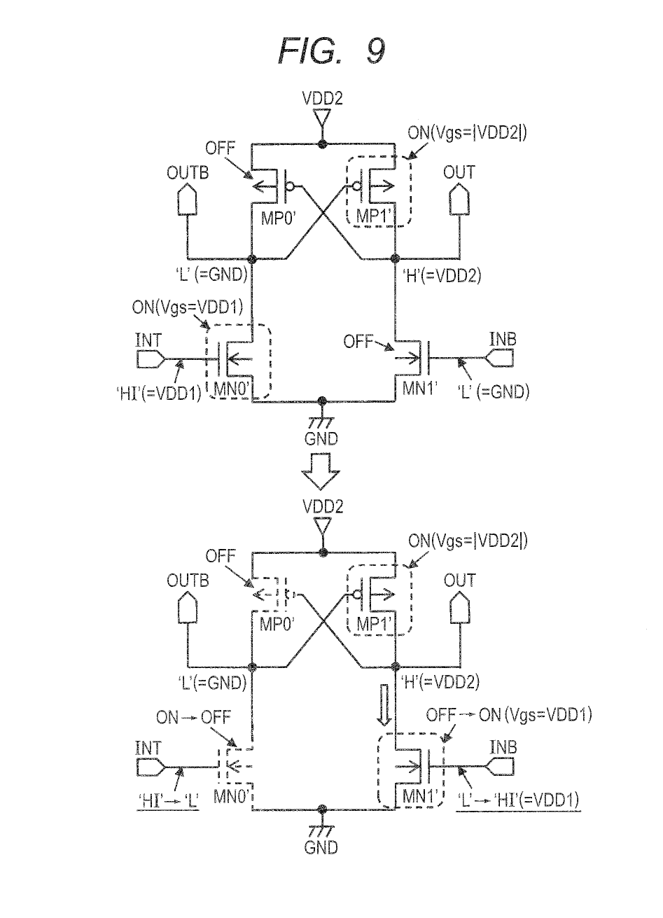

FIG. 9 is a circuit diagram showing an exemplary configuration and an exemplary main operation of a level shift circuit used as a comparative example of the invention. The level shift circuit shown in FIG. 9 includes the input node INT and the inverted input node INB, the output node OUT and an inverted output node OUTB, a pair of NMOS transistors MN0′m MN1′, and a pair of PMOS transistors MP0′, MP1′. The input node INT and the inverted input node INB receive input an signal (INT) and an inverted input signal (INB) having a polarity opposite from that of the input signal (INT), respectively, and the output node OUT and the inverted output node OUTB output an output signal (OUT) and an inverted output signal (OUTB) having a polarity opposite from that of the output signal (OUT), respectively.

The NMOS transistor MN0′ is arranged between the inverted output node OUTB and the reference power supply potential GND, and driven by the input signal (INT). The NMOS transistor MN1′ is arranged between the output node OUT and the reference power supply potential GND, and driven by the inverted input signal (INB). The PMOS transistor MP0′ is arranged between the external power supply potential VDD2 and the inverted output node OUTB, and driven by the output signal (OUT). The PMOS transistor MP1′ is arranged between the external power supply potential VDD2 and the output node OUT, and driven by the inverted output signal (OUTB).

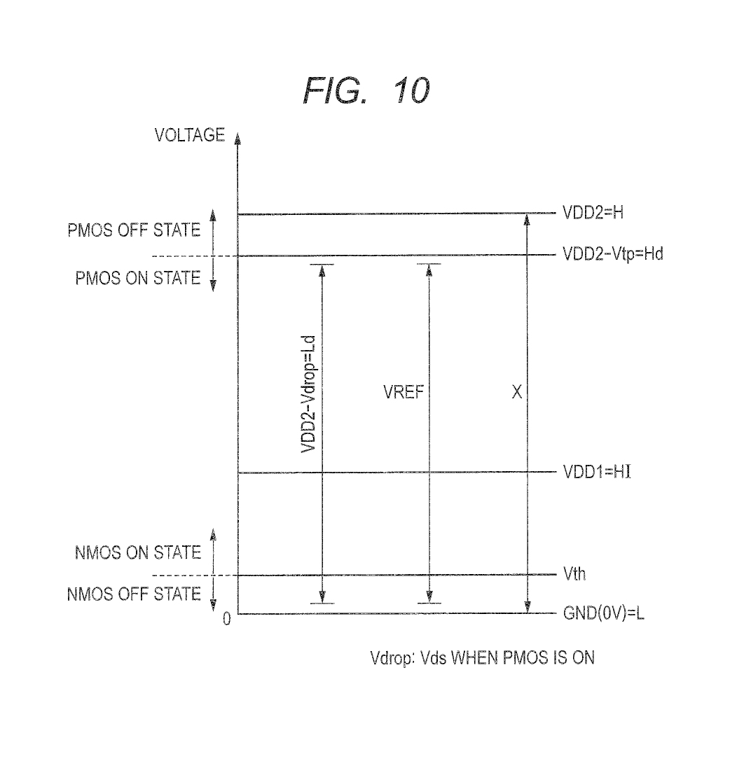

FIG. 10 is a diagram defining a potential of each signal and an operational state of each transistor used herein. As shown in FIG. 10, in this specification, the state in which the signal potential is the reference power supply potential GND is denoted by “‘L’, the state in which the signal potential is the external power supply potential VDD2 is denoted by ‘H’, and the state in which the signal potential is the external power supply potential VDD1 is denoted by ‘Hl’. Moreover, when assuming a threshold voltage of the PMOS transistor as Vtp, the state in which the signal potential is “VDD2−Vtp” is denoted by ‘Hd’.

For example, referring to FIG. 9, each PMOS transistor of which source is applied with the external power supply potential VDD2 falls into a boundary state between ON and OFF when ‘Hd’ is applied to its gate (i.e., when the gate-source voltage (referred to as Vgs) is |Vtp|). Each PMOS transistor falls into an OFF state when ‘Hd’ to “H” is applied to its gate and an ON state when ‘L’ to ‘LHd’ is applied. On the other hand, assuming its threshold voltage as Vtn, each NMOS transistor of which source is applied with the reference power supply potential GND falls into the boundary state between ON and OFF when Vtn is applied to its gate (when Vgs=Vtn), the OFF state when ‘L’ to Vtn is applied, and the ON state when Vtn to ‘H’ is applied.

With reference to FIG. 9, a case is presumed in which both the PMOS transistor (for example, MP0′) and the NMOS transistor (MN0′) coupled in series between the external power supply potential VDD2 and the reference power supply potential GND are turned on. Assuming the drain-source voltage Vds of the PMOS transistor in this case as Vdrop (|Vtp|<Vdrop<VDD2), “VDD2−Vdrop” is referred to as ‘Ld’. That is, the potential of ‘Ld’ is determined by a ratio of driving abilities (on resistance) of the PMOS transistor and NMOS transistor, which makes 0<Ld<Hd. Although details will be described later, VREF is a fixed potential set in the range of 0<VREF<Hd, and ‘X’ is an unfixed potential which can range from ‘L’ to ‘H’.

An upper part of FIG. 9 shows a circuit state when it is steady with the input node INT being ‘Hl’ and the inverted input node INB being ‘L’. In this case, the NMOS transistor MN0′ and the PMOS transistor MP1′ are on and the NMOS transistor MN1′ and the PMOS transistor MP0′ are off. Furthermore, the output node OUT is ‘H’ and the inverted output node OUTB is ‘L’.

Starting from this state, a lower part of FIG. 9 shows the circuit state when the input node INT transitions from ‘Hl’ to ‘L’ (the inverted input node INB transitions from ‘L’ to ‘H’). The NMOS transistor MN1′ transitions from OFF to ON according to the transition of the inverted input node INB, and the NMOS transistor MN0′ transitions from ON to OFF according to the transition of the input node INT.

In this manner, preferably the NMOS transistor MN1′ makes the output node OUT transition from ‘H’ to a potential lower than ‘Hl’, which in turn makes the PMOS transistor MP0′ transition from off to on. When the PMOS transistor MP0′ transitions to on, the inverted output node OUTB transitions toward ‘H’ and the PMOS transistor MP1′ transitions toward off. The NMOS transistor MN1′ can easily make the output node OUT transit to ‘L’ with the transition of the PMOS transistor MP1′.

Actually, however, when the NMOS transistor MN1′ is making the output node OUT transition from ‘H’ to the potential lower than ‘Hl’, the gate of the PMOS transistor MP1′ is applied with ‘L’ by the inverted output node OUTB in a floating state. Thus, because Vgs is at the level of VDD2, the PMOS transistor MP1′ is turned on in a state in which a high drain-source current (hereinafter, referred to as Ids) can flow.

If the Ids that the NMOS transistor MN1′ can allow is ever lower than the Ids that the PMOS transistor MP1′ can allow, then it may be difficult for the NMOS transistor MN1′ to make the output node OUT transit to the potential lower than ‘Hd’. The IDS of the transistor depends on Vgs. While the Vgs of the NMOS transistor MN1′ is at the level of VDD1, the Vgs of the PMOS transistor MP1′ is at the level of VDD2. Consequently, there is a risk that, as the difference between the external power supply potential VDD2 and the internal power supply potential VDD1 increases (for example, VDD1 decreases relatively), it may become more difficult for the output node OUT to transition, resulting in a limited power supply potential range that allows the level shift operation.

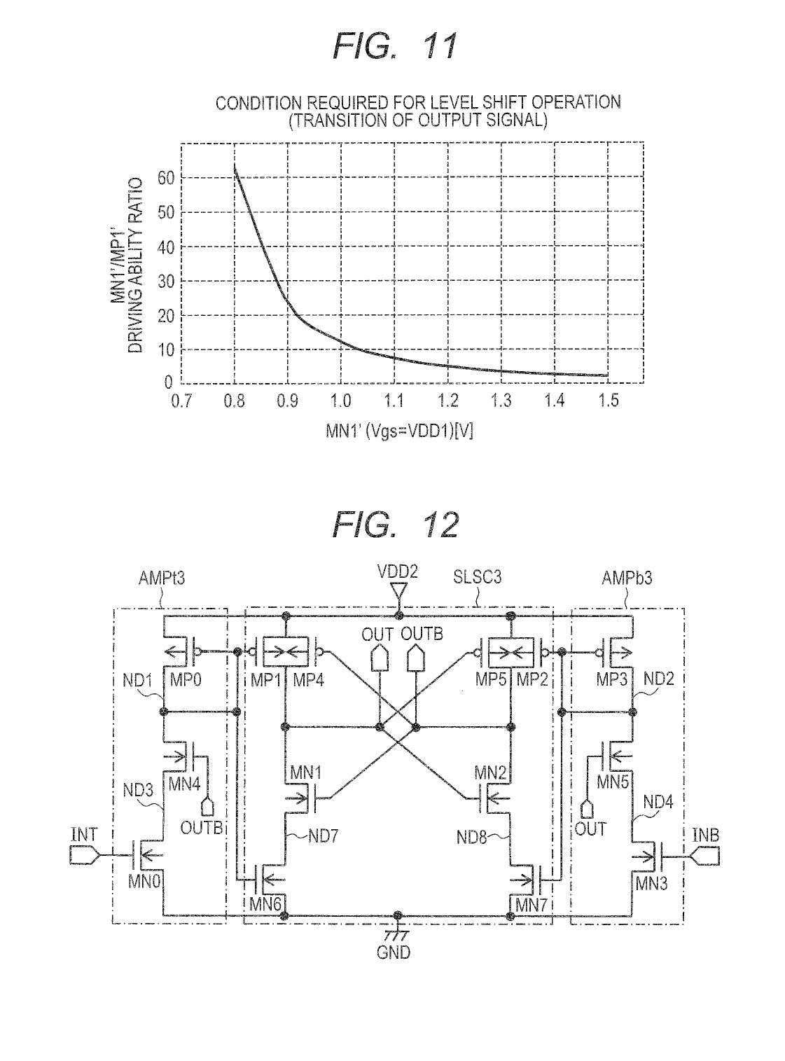

FIG. 11 is a diagram specifically illustrating one example of problems associated with the level shift circuit in FIG. 9. One approach to achieve a correct level shift operation in FIG. 9 may be making the driving ability (in other words, transistor size) of the NMOS transistor (for example, MN1′) sufficiently higher than the driving ability of the PMOS transistor (MP1′). FIG. 11 shows one example of the size ratio of the NMOS transistor MN1′ to the PMOS transistor MP1′ required to achieve the proper level shift operation (normal transition of output signal (OUT)), where VDD2=5.0 V, and the threshold voltage of the PMOS transistor MP0′, MP1′ is 10 V.

For example, when the internal power supply voltage VDD1 (=Vgs of the NMOS transistor MN1′) is 1.5 V, the correct level shift operation can be performed by setting the size of the NMOS transistor MN1′ 2.5 times or more of the PMOS transistor MP1′. On the other hand, when the internal power supply voltage VDD1 is 1.0 V, the size of the NMOS transistor MN1′ must be set to be 13 times or more, and when 0.9 V and 0.8 V, it must be set at 24 times or more and 63 times or more, respectively. Consequently, the larger the difference between the external power supply potential VDD2 and the internal power supply potential VDD1, the more the circuit area can increase.

Furthermore, increase of the circuit area may influence the operation speed. For example, in FIG. 9, the diffusion capacitances (drain capacitances) of the PMOS transistor MP1′ and the NMOS transistor MN1′ are focused on among the capacitances that appear at the output node OUT. The diffusion capacitance when the internal power supply voltage VDD1 is calculated to be 1.5 V is 3.5 (=1+2.5) by totaling the sizes of the PMOS transistor MP1′ and the NMOS transistor MN1′, and the diffusion capacitance when the internal power supply voltage VDD1 is 1.0 V is calculated in the same manner to be 14 (=1+13). Thus, the diffusion capacitance when the internal power supply voltage VDD1 is 1.0 V is four times larger than that when the internal power supply voltage VDD1 is 1.5 V.

As the capacitance increases in this manner, the time required for charge and discharge when the output signal (OUT) transitions increases, which may lower the operation speed. One approach to improve the operation speed can be increasing the drive current, but this approach may possibly be constrained. Specifically, for example, a case is assumed in which the transistor size of the PMOS transistor MP1′ is increased in order to increase the drive current. In this case, as described above, as the difference between the external power supply potential VDD2 and the internal power supply potential VDD1 increases, a larger output capacitance is applied by the NMOS transistor MN1′, which may inhibit the improvement in the operation speed. Therefore, in order to improve the operation speed by controlling the drive current, it can be required that the difference between the external power supply potential VDD2 and the internal power supply potential VDD1 be reasonably small.

As described above, in the level shift circuit shown in FIG. 9, as the difference between the external power supply potential VDD2 and the internal power supply potential VDD1 increases (for example, VDD lowers relatively), it can become difficult to perform the level shift operation while satisfying the predetermined performance. Specifically, for example, it can become difficult to perform the level shift operation while reducing the circuit area and improving the operation speed. As a result, in view of actual use, there is a risk of reducing the power supply potential range in which the level shift operation can be performed.

### <<Configuration of Level Shift Circuit (First Embodiment)>>

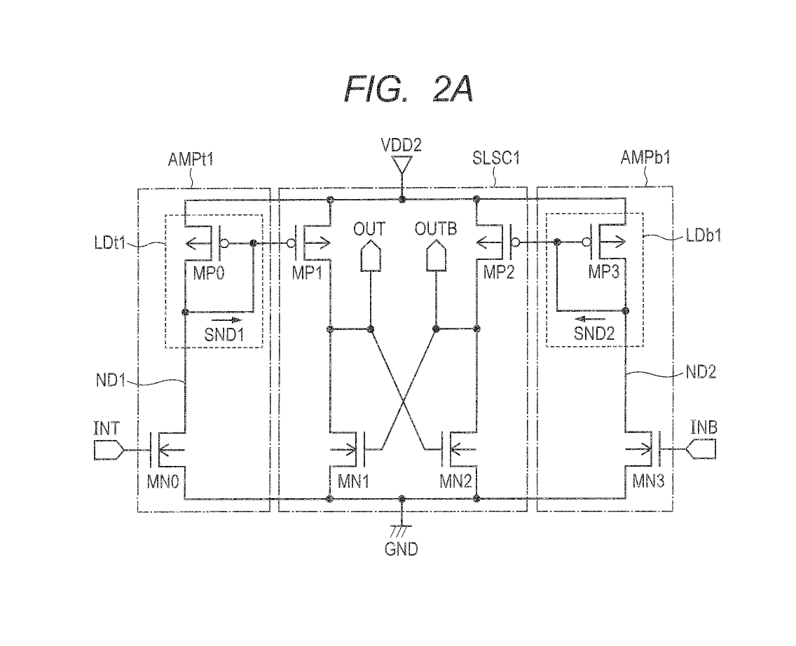

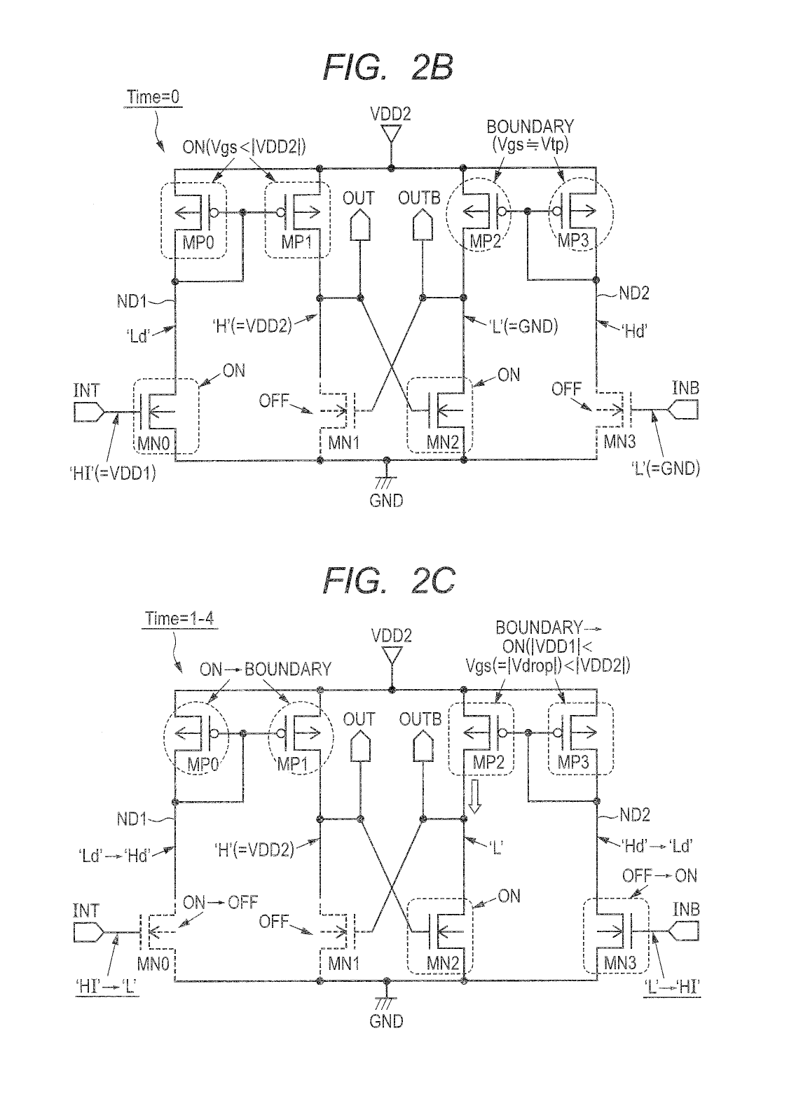

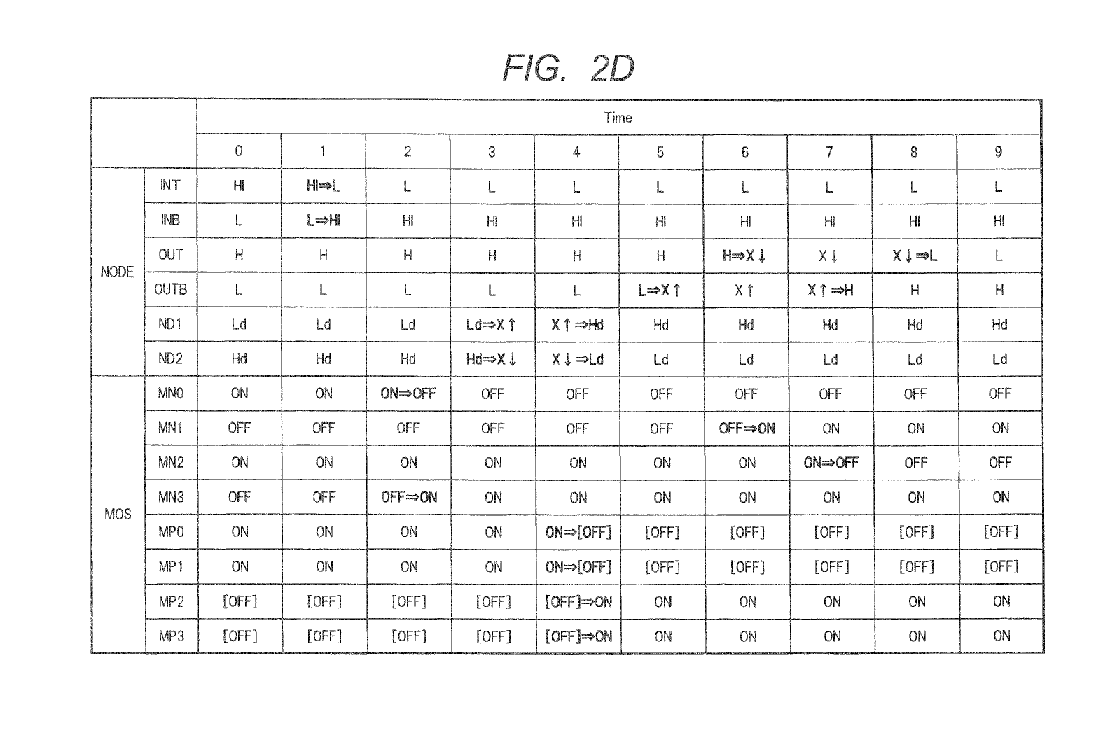

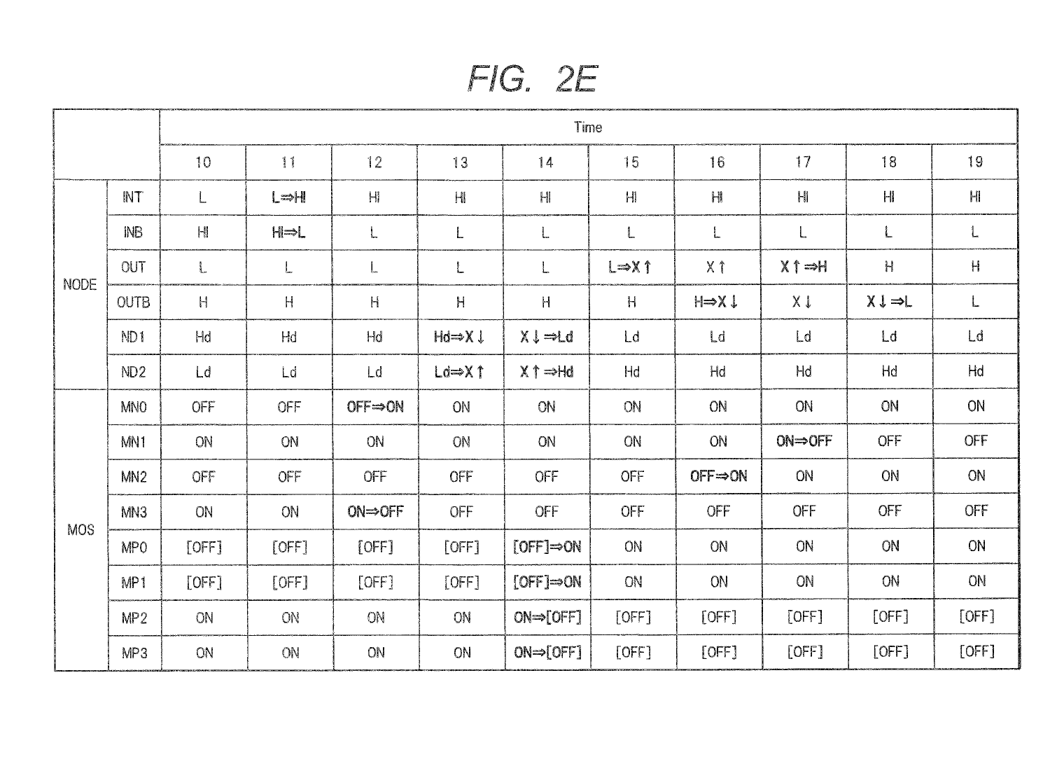

FIG. 2A is a circuit diagram showing an exemplary configuration of a level shift circuit according to the first embodiment of the invention. The level shift circuit shown in FIG. 2A includes amplitude amplifying circuits AMPt1, AMPb1 and a sublevel shift circuit SLSC1, in addition to the input node INT, the inverted input node INB, the output node OUT, and the inverted output node OUTB as in FIG. 9. The amplitude amplifying circuits AMPt1, AMPb1 and the sublevel shift circuit SLSC1 are all supplied with the reference power supply potential GND and the external power supply potential VDD2.

The amplitude amplifying circuits AMPt1, AMPb1 outputs signals SND1, SND2 having a voltage amplitude larger than the VDD1 amplitude and smaller than the VDD2 amplitude to nodes ND1, ND2 in response to the input signal (INT) and the inverted input signal (INB) having the VDD1 amplitude from the input node INT and the inverted input node INB, respectively. The sublevel shift circuit SLSC1 outputs the output signal (OUT) and the inverted output signal (OUTB) having the VDD2 amplitude to the output node OUT and the inverted output node OUTB in response to the signals SND1, SND2 from the amplitude amplifying circuits AMPt1, AMPb1.

Specifically, the amplitude amplifying circuit AMPt1 includes an NMOS transistor NM0 and a load circuit LDt1. In the NMOS transistor NM0, a drain-source path is arranged between the node ND1 and the reference power supply potential GND, and the gate is driven by the input signal (INT). The load circuit LDt1 is arranged between the external power supply potential VDD2 and the node ND1, and outputs a signal SND1 that depends on the current flowing through the NMOS transistor NM0 to the node ND1. The load circuit LDt1 herein includes a PMOS transistor MP0 in which a source-drain path is arranged between the external power supply potential VDD2 and the node ND1 and of which gate is driven by the signal SND1 of the node ND1.

Similarly, the amplitude amplifying circuit AMPb1 includes an NMOS transistor MN3 and a load circuit LDb1. In the NMOS transistor MN3, the drain-source path is arranged between the node ND2 and the reference power supply potential GND, and its gate is driven by the inverted input signal (INB). The load circuit LDb1 is arranged between the external power supply potential VDD2 and the node ND2, and outputs a signal SND2 that depends on the current flowing through the NMOS transistor MN3 to the node ND2. The load circuit LDb1 herein includes a PMOS transistor MP3 in which the source-drain path is arranged between the external power supply potential VDD2 and the node ND2 and of which gate is driven by the signal SND2 of the node ND2.

The sublevel shift circuit SLSC1 includes a pair of NMOS transistors MN1, MN2 and a pair of PMOS transistors MP1, MP2. In the NMOS transistor MN1, the drain-source path is arranged between the output node OUT and the reference power supply potential GND, and its gate is driven by the inverted output signal (OUTB). In the NMOS transistor MN2, the drain-source path is arranged between the inverted output node OUTB and the reference power supply potential GND, and its gate is driven by the output signal (OUT).

In the PMOS transistor MP1, the source-drain path is arranged between the external power supply potential VDD2 and the output node OUT, and its gate is driven by the signal SND1 of the node ND1. In the PMOS transistor MP2, the source-drain path is arranged between the external power supply potential VDD2 and the inverted output node OUTB, and its gate is driven by the signal SND2 of the node ND2.

The sublevel shift circuit SLSC1 has a configuration similar to the circuit shown in FIG. 9 with a pair of NMOS transistors being replaced by a pair of PMOS transistor. As a result, while the circuit shown in FIG. 9 coverts the voltage amplitude of the signal based on the reference power supply potential GND, the sublevel shift circuit SLSC1 converts the voltage amplitude of the signal based on the external power supply potential VDD2. Except this, basically these two circuits operate substantially in the same manner.

However, as a major difference, it should be noted that the sublevel shift circuit SLSC1 performs the level shift operation in response to the signals SND1, SND2 having a voltage amplitude larger than the VDD1 amplitude from the amplitude amplifying circuits AMPt1, AMPb1 and smaller than the VDD2 amplitude, unlike the circuit shown in FIG. 9. Moreover, one feature of the amplitude amplifying circuits AMPt1, AMPb1 would be the fact that the PMOS transistors MP0, MP3 are driven to be ON with the voltage amplitude smaller than the VDD2 amplitude.

### <<Operation of Level Shift Circuit (First Embodiment)>>

FIG. 2B is a circuit diagram showing an exemplary state of each node and each transistor in a steady state in FIG. 2A, and FIG. 2C is a circuit diagram showing an example of a state transition of each node and each transistor during a transition period in FIG. 2A. FIG. 2D is a transition diagram summarizing one example of a time-series state transition of each node and each transistor associated with transition of an input signal in FIG. 2A, and FIG. 2E is a transition diagram summarizing one example of a time-series state transition of each node and each transistor associated with the transition of the input signal in a direction opposite from FIG. 2D.

Each period (Time) shown in the transition diagram of FIG. 2D is sectioned for convenience in view of state transition, the lengths of which periods are not necessarily the same. Meaning of each potential used in the transition diagram is as shown in FIG. 10. In addition, in the transition diagram, a state in which the potential of the node is raised is indicated by “X (upward arrow)” and a state in which the potential is dropped is indicated by “X (downward arrow)”. The state of the transistor “[OFF]” does not mean a complete “OFF” but a boundary state between ON and OFF. The same applies to the transition diagram shown in FIG. 2E and other transition diagrams used in later embodiments.

First, a case is described in which the input node INT transitions from ‘Hl’ (=VDD1) to ‘L’ and the output node OUT transitions from ‘H’ (=VDD2) to ‘L’ accordingly. In the initial period (Time=0) (in other words, steady state) in FIG. 2D, the nodes and the transistors are in such a state as shown in FIG. 2B. At “Time=0” in FIG. 2D and in FIG. 2B, the input node INT is ‘Hl’ and the inverted input node INB is ‘L’. Accordingly, the NMOS transistor NM0 is ON and the NMOS transistor MN3 is OFF.

The node ND1 is ‘Ld’ (=VDD2−Vdrop) according to the NMOS transistor NM0 being turned ON. The Vdrop is the drain-source voltage Vds (=Vgs) applied to the PMOS transistor MP0 when the Ids of the PMOS transistor MP0 and the Ids the NMOS transistor NM0, both of which are in the ON state, are balanced. The PMOS transistor MP1 is ON according to ‘Ld’ of the node ND1.

The node ND2 is ‘Hd’ (=VDD2−|Vtp|) according to the NMOS transistor MN3 being OFF. Accordingly, the PMOS transistors MP3, MP2 fall into the boundary state between ON and OFF. The output node OUT is ‘H’, and the inverted output node OUTB is ‘L’. Accordingly, the NMOS transistor MN2 is ON and the NMOS transistor MN1 is OFF.

Now, explanation is given about “Time=1 to 4” in FIG. 2D. The state transition in the period substantially corresponding to the “Time=1 to 4” is shown in FIG. 2C. When the input node INT transitions from ‘Hl’ to ‘L’ at the “Time=1” in FIG. 2D, the NMOS transistor NM0 transitions from ON to OFF at the “Time=2”. The node ND1 transitions from ‘Ld’ to ‘Hd’ at the “Time=3” and later by the NMOS transistor NM0 transitioning to OFF. Accordingly, the PMOS transistors MP0, MP1 transitions from ON to the boundary state.

On the other hand, when the inverted input node INB transitions from ‘L’ to ‘Hl’ at “Time=1” in FIG. 2D, the NMOS transistor MN3 transitions from OFF to ON at “Time=2”. At the timing of transition, the node ND is ‘Hd’ and the Vgs of the PMOS transistor MP3 is Vtp. When Vgs=Vtp, the Ids of the PMOS transistor MP3 is ideally 0. Thus, at the “Time=3” and later, the NMOS transistor MN3 can easily lower the potential of the node ND2 even when the Ids is low according to Vgs=‘Hl’ (=VDD1).

In other words, the PMOS transistor MP3 is not a transistor that is driven to be ON with the VDD2 amplitude as shown in FIG. 9 but a transistor that is driven to be ON with the voltage amplitude lower than the VDD2 amplitude. Consequently, the NMOS transistor MN3 can lower the drain potential of the PMOS transistor MP (potential of the node ND2) more easily than in the case of FIG. 9.

When the potential of the node ND2 is lowered, the PMOS transistors MP3, MP2 both transitions from the boundary state to ON and the node ND2 falls into ‘Ld’. Moreover, by the PMOS transistor MP2 transitioning to ON, the inverted output node OUTB is raised from ‘L’. At this point, however, as shown in FIG. 2C, because the NMOS transistor MN2 is also ON along with the output node OUT being ‘H’(=VDD2), a raising ability of the inverted output node OUTB can become a problem for the reason similar to the case of FIG. 9.

In the case of FIG. 9, the drain potential of the PMOS transistor MP1′ driven to be ON by the VDD2 amplitude is raised by the NMOS transistor MN1′ that is driven to be ON by the VDD1 amplitude. On the other hand, in the case of FIG. 2C, the drain potential of the NMOS transistor MN2 driven to be ON by the VDD2 amplitude is raised by the PMOS transistor MP2 driven to be ON by the |Vdrop| amplitude. In this case, the amplitude amplifying circuit AMPb1 plays a role of amplifying the inverted input signal (INB) of the VDD1 amplitude to the signal SND2 of the |Vdrop| amplitude larger than the VDD1 amplitude and smaller than the VDD2 amplitude and outputting the resulting signal to the sublevel shift circuit SLSC1. Thus, it is possible to insure sufficient raising ability of the inverted output node OUTB by setting the input voltage amplitude of the sublevel shift circuit SLSC1 not to the VDD1 amplitude but to the |Vdrop| amplitude.

When the inverted output node OUTB is raised from ‘L’ to Vtn at the “Time=5” in FIG. 2D, the NMOS transistor MN1 is transitioned from OFF to ON at the “Time=6”, and the output node OUT drops from ‘H’. When the output node OUT is dropped below Vtn, the NMOS transistor MN2 transitions from ON to OFF at the “Time=7”, and accordingly the inverted output node OUTB is to ‘H’. Moreover, the output node OUT rests at ‘L’ via the NMOS transistor MN1 in the ON state at the “Time=8”, and falls into the steady state in which the input signal INT is ‘L’ at Time=9.

The steady state where the input signal INT is ‘L’ is a state in which one state is exchanged by the other state in a symmetric relation thereto shown in FIG. 2B. Specifically, INT, OUT, ND1, MN0, MN1, MP0, and MP1 are exchanged by INB, OUTB, ND2, MN3, MN2, MP3, and MP2, respectively. Moreover, contrary to the “Time=0 to 9” in FIG. 2D, the “Time=10 to 19” in FIG. 2E show a transition state of the input node INT transitioning from ‘L’ to ‘Hl’. The transition state in FIG. 2E is also a state in which one state is exchanged by the other state in a symmetric relation thereto shown in FIG. 2D.

In other words, for example, the state of the input node INT in FIG. 2E turns to the state of the inverted input node INB in FIG. 2D, and the state of the inverted input node INB in FIG. 2E turns to the state of the input node INT in FIG. 2D. Furthermore, the state of the NMOS transistor NM0 in FIG. 2E turns to the state of the NMOS transistor MN3 in FIG. 2D, and the state of the NMOS transistor MN3 in FIG. 2E turns to the state of the NMOS transistor NM0 in FIG. 2D.

### <<Major Effect of First Embodiment>>

As described above, in the first embodiment, unlike the case of FIG. 9, when transitioning the drain potential of the MOS transistor (for example, MP3) on the opposite side that is in the ON state using the MOS transistor (MN3) that is driven to be ON by the VDD1 amplitude, Vgs of the MOS transistor on the opposite side can be set to a value smaller than |VDD2|. Furthermore, when transitioning the drain potential of the MOS transistor (for example, MN2) using the MOS transistor (MP2) on the opposite side, Vgs of the MOS transistor on the opposite side can be set to the voltage amplitude larger than the VDD1 amplitude.

From the above, it is possible to perform the level shift operation while satisfying the predetermined performance even when the difference between the external power supply potential VDD2 and the internal power supply potential VDD1 increases. Specifically, for example, when performing the level shift operation in the same power supply potential range with the exemplary configurations shown in FIGS. 2A and 9, it is possible in FIG. 2A to set the size ratio of the PMOS transistor to the NMOS transistor than in FIG. 9, thereby achieving reduction of the circuit area and reduction of parasitic capacitance (and thus improvement of the operation speed). Moreover, when the exemplary configuration in FIG. 9 can achieve a certain operation speed in a certain power supply potential range, the exemplary configuration in FIG. 2A can achieve the same operation speed in the power supply potential range wider than that in FIG. 9. As a result, it is possible to increase the power supply potential range that can allow the level shift operation.

### Second Embodiment

### <<Configuration of Level Shift Circuit (Second Embodiment)>>

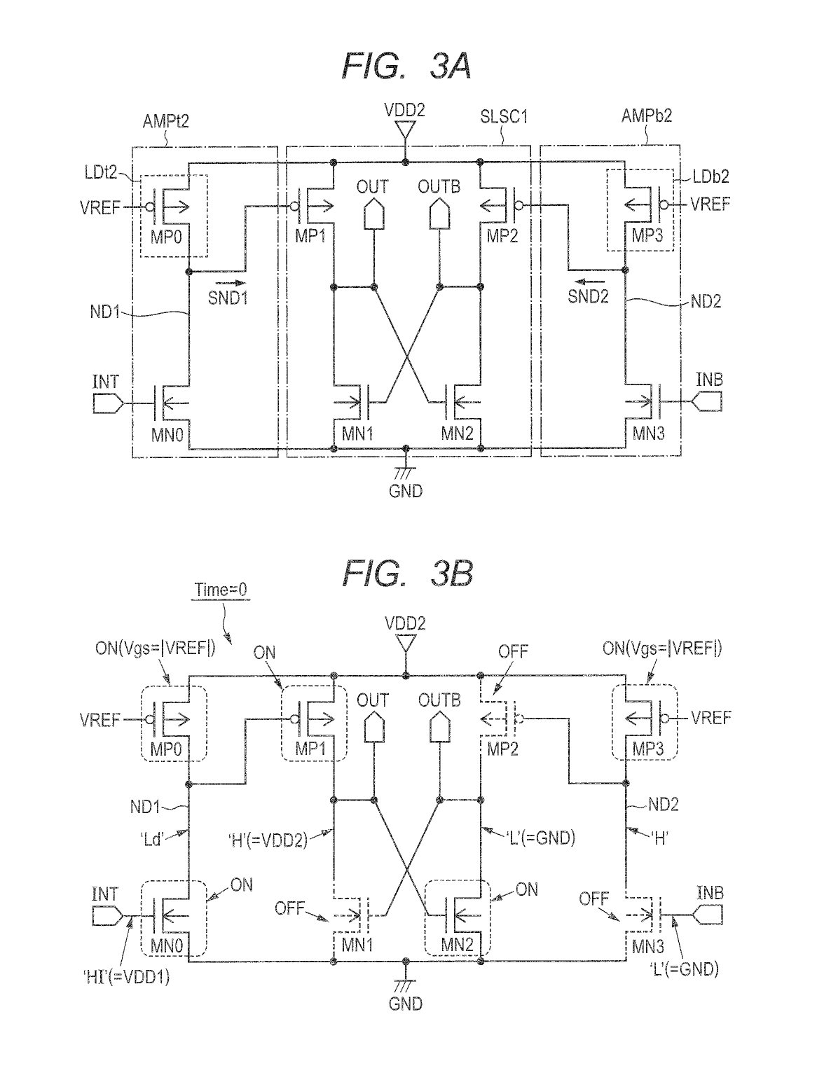

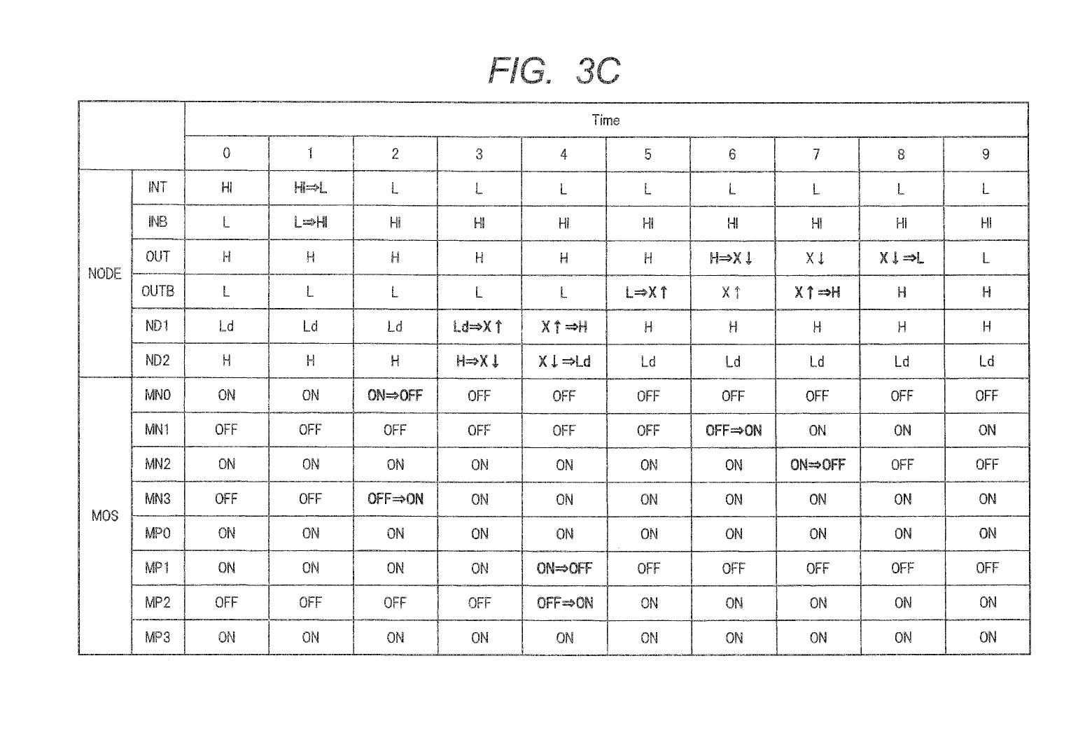

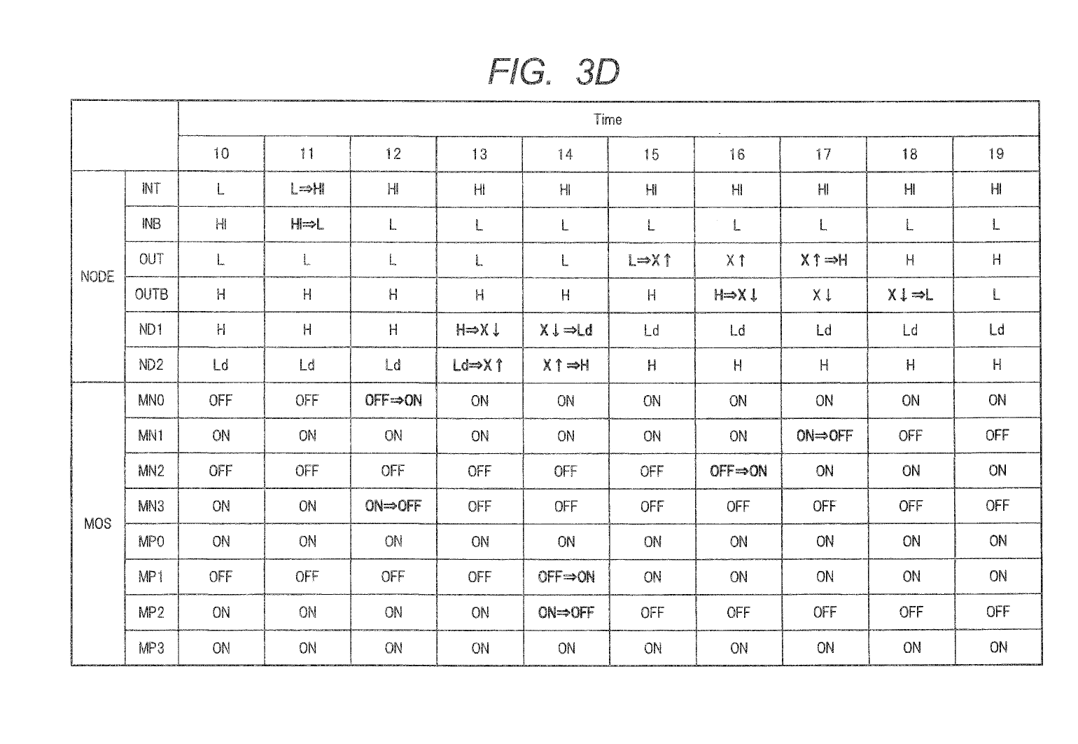

FIG. 3A is a circuit diagram showing an exemplary configuration of a level shift circuit according to a second embodiment of the present invention. The level shift circuit shown in FIG. 3A is different from the level shift circuit in FIG. 2A in configuration of load circuits LDt2, LDb2 in amplitude amplifying circuits AMPt2, AMPb2. As in the case of FIG. 2A, the load circuit LDt2 includes the PMOS transistor MP0 in which the source-drain path is arranged between the external power supply potential VDD2 and the node ND1, and the load circuit LDb2 includes the PMOS transistor MP3 in which the source-drain path is arranged between the external power supply potential VDD2 and the node ND2. It should be noted, however, that the PMOS transistors MP0, MP3 are driven to be ON by a preset fixed potential VREF, unlike the case of FIG. 2A.

The fixed potential VREF is generated by an unshown potential generation circuit and, as shown in FIG. 10, set to any potential within a range of 0<VREF<(VDD2−|Vtp|). Here, the fixed potential VREF plays mainly two roles as in the first embodiment. The first role is to set Ids of the PMOS transistors MP0, MP3 to sufficiently small value (Ids is not equal to 0) so as to be able to easily reduce the potential of the nodes ND1, ND2 by the NMOS transistors NM0, MN3.

The second role is to set the voltage amplitudes of the signals SND1, SND2 to an amplitude larger than the VDD1 amplitude and smaller than the VDD2 amplitude. In doing this, the input voltage amplitude of the sublevel shift circuit SLSC1 is preferred to be larger, and therefore the voltage amplitudes of the signals SND1, SND2 are preferred to be closer to VDD2 amplitude. From this perspective, the value of the fixed potential VREF is preferred to be closer to “VDD2−|Vtp|” in FIG. 10. In this case, each of the PMOS transistors MP0, MP3 functions as a constant current load with a high resistance.

### <<Operation of Level Shift Circuit (Second Embodiment)>>

FIG. 3B is a circuit diagram showing an exemplary state of each node and each transistor in the steady state in FIG. 3A. FIG. 3C is a transition diagram summarizing one example of a time-series state transition of each node and each transistor associated with transition of an input signal in FIG. 3A, and FIG. 3D is a transition diagram summarizing one example of a time-series state transition of each node and each transistor associated with the transition of the input signal in a direction opposite from FIG. 3C.

Shown at “Time=0” in FIGS. 3B and 3C is the state of each node and each transistor when the input node INT is ‘Hl’. The state shown in FIG. 3B is different from the state in FIG. 2B in that the PMOS transistors MP0, MP3 are always driven to be ON by the fixed potential VREF, that the node ND2 accordingly falls into ‘H’ instead of ‘Hd’, and that, according to the ‘H’, the PMOS transistor MP2 is not in the boundary state but OFF.

Despite these differences, the state transitions shown in FIGS. 3C and 3D are essentially the same as the state transitions shown in FIGS. 2D and 2E. In other words, the state transitions in FIGS. 3C and 3D can be obtained by always keeping the PMOS transistors MP0, MP3 ON, exchanging ‘Hd’ by ‘H’, and exchanging “[OFF]” by “OFF” in FIGS. 2D and 2E.

### <<Major Effect of Second Embodiment>>

As described above, it is possible to obtain the effect similar to that in the first embodiment by using the level shift circuit according to the second embodiment. Furthermore, compared with the first embodiment, although the level shift circuit in the second embodiment needs a circuit for generating the fixed potential VREF, Vgs values of the PMOS transistors MP0, MP3 are fixed, and therefore it is theoretically possible to increase the |Vdrop| amplitudes of the signals SND1, SND2. In other words, with the configuration of the first embodiment, because |Vdrop| (=drain-source voltage Vds) of the PMOS transistors MP0, MP3 can be equal to Vgs, the ON resistance of the PMOS transistors MP0, MP3 reduces as |Vdrop| increases, consequently inhibiting increase in |Vdrop|. The configuration of the second embodiment will not cause such a problem.

As can be seen from the role of the PMOS transistors MP0, MP3, the PMOS transistors MP0, MP3 can be replaced by high resistance elements or the like in some cases. Moreover, the level shift circuit described in each of the following embodiments includes the load circuits LDt1, LDb1 for convenience, but it may include the load circuits LDt2, LDb2 of the second embodiment, or even the high resistance elements in some cases, instead of the load circuits LDt1, LDb1.

### Third Embodiment

### <<Configuration of Level Shift Circuit (Third Embodiment)>>

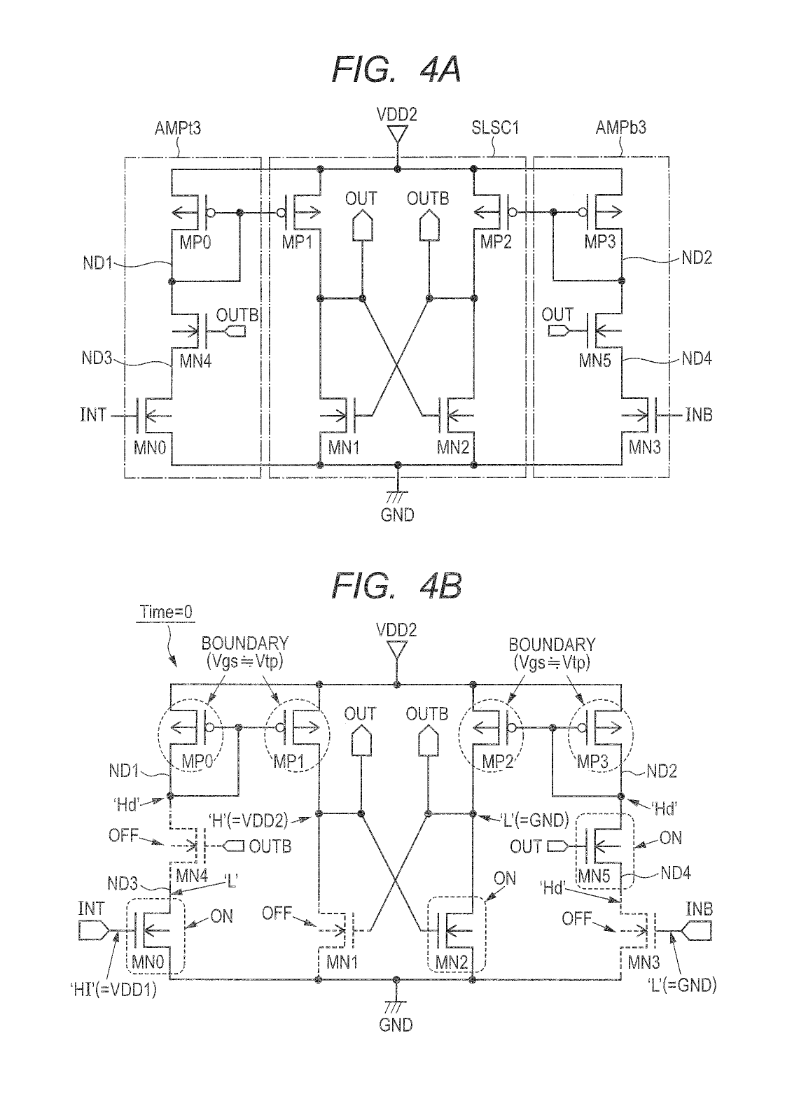

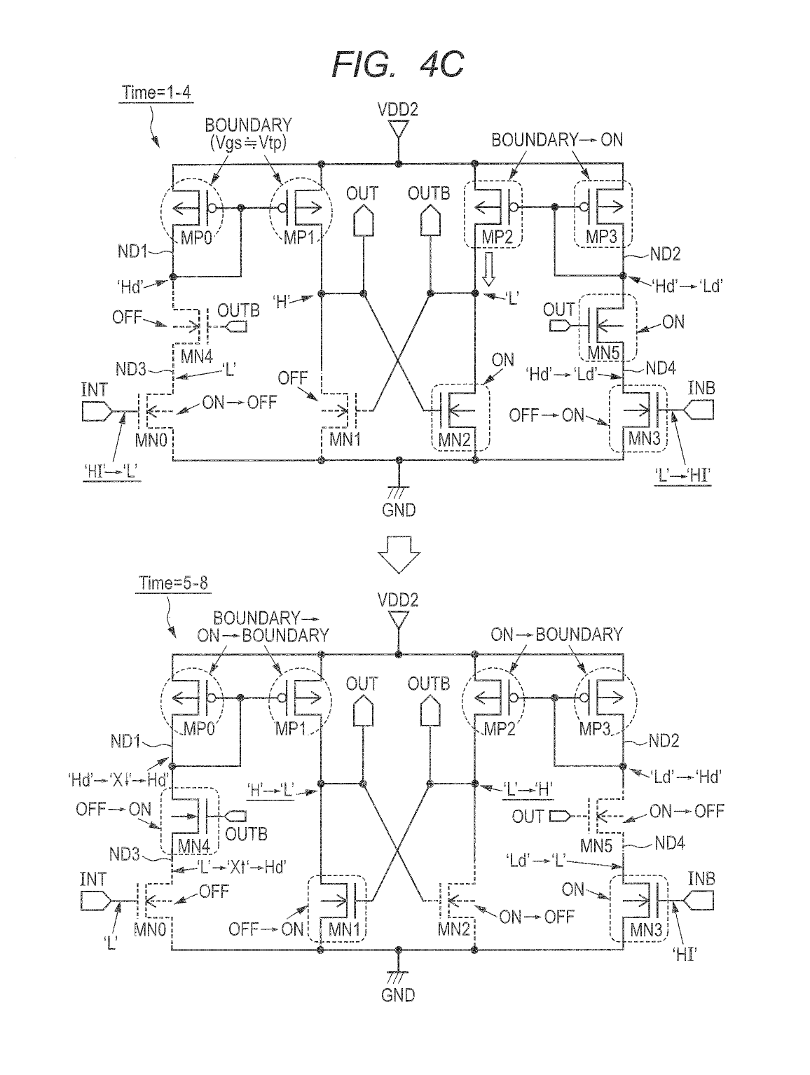

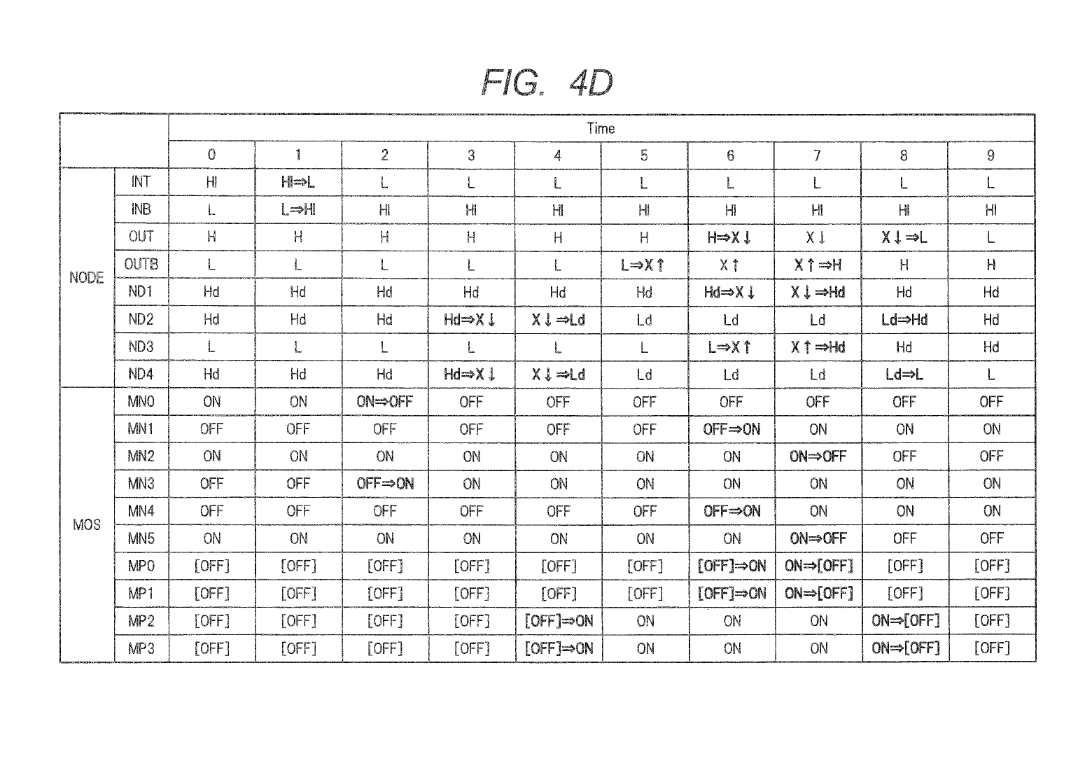

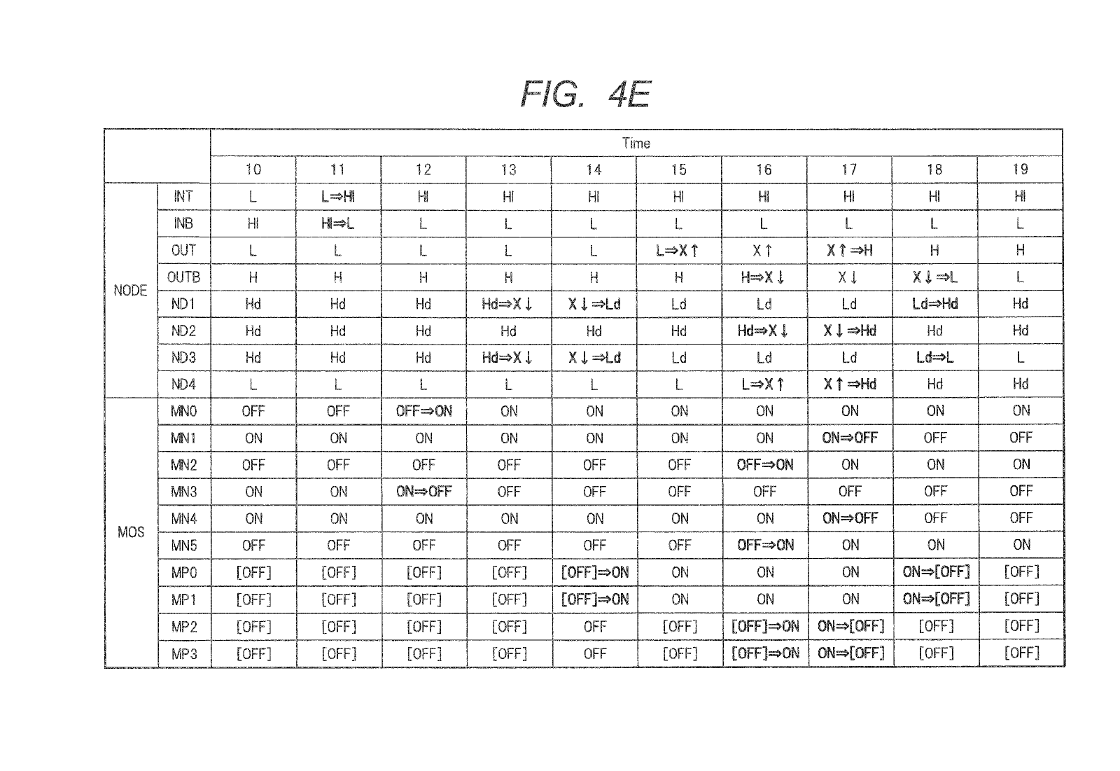

FIG. 4A is a circuit diagram showing an exemplary configuration of a level shift circuit according to a third embodiment of the invention. The level shift circuit shown in FIG. 4A includes amplitude amplifying circuits AMPt3, AMPb3 different from the level shift circuits shown in FIG. 2A. The amplitude amplifying circuit AMPt3 additionally includes an NMOS transistor MN4, and the amplitude amplifying circuit AMPb3 additionally includes an NMOS transistor MN5. The MOS transistor MN4 is provided with the drain-source path between the node ND1 and the NMOS transistor NM0, and its gate is driven by the inverted output signal (OUTB). On the other hand, the NMOS transistor MN5 is provided with the drain-source path between the node ND2 and the NMOS transistor MN3, and its gate is driven by the output signal (OUT).

Here, the NMOS transistors MN4, MN5 play the role of reducing electric power consumed by the amplitude amplifying circuits AMPt3, AMPb3. That is, in each amplitude amplifying circuit shown in FIGS. 2A and 3A described above, through current is generated in the steady state. In one specific example, the amplitude amplifying circuit AMPt1 in FIG. 2A generates the through current in the steady state in which the input node INT is ‘Hl’. The NMOS transistors MN4, MN5 function as switches to prevent the through current in the steady state.

When regarding the NMOS transistor MN4 as a switch, it is controlled to be ON according to the transition of the inverted output signal (OUTB) to ‘H’ or the transition of the output signal (OUT) to ‘L’. Similarly, when regarding the NMOS transistor MN5 as a switch, it is controlled to be ON according to the transition of the output signal (OUT) to ‘H’ or the transition of the inverted output signal (OUTB) to ‘L’.

It is noted that each of the NMOS transistors MN4, MN5 can be replaced by the PMOS transistor by aligning the polarity is aligned, in some cases. For example, when the NMOS transistor MN4 is replaced by the PMOS transistor, it suffices to drive the gate of the PMOS transistor by the output signal (OUT). It should be noted in this case that, for example, it is preferred to use the NMOS transistor because the potential of the node ND1 cannot be reduced to |Vtp| or lower when both the NMOS transistor NM0 and the PMOS transistor are ON.

### <<Operation of Level Shift Circuit (Third Embodiment)>>

FIG. 4B is a circuit diagram showing an exemplary state of each node and each transistor in the steady state in FIG. 4A, and FIG. 4C is a circuit diagram showing one example of the state transition of each node and each transistor during a transition period in FIG. 4A. FIG. 4D is a transition diagram summarizing one example of a time-series state transition of each node and each transistor associated with transition of an input signal in FIG. 4A, and FIG. 4E is a transition diagram summarizing one example of a time-series state transition of each node and each transistor associated with the transition of the input signal in a direction opposite from FIG. 4D.

In the initial period (Time=0) in FIG. 4D (in other words, steady state), as shown in FIG. 4B, the input node INT is ‘Hl’ and the inverted input node INB is ‘L’. Accordingly, the NMOS transistor NM0 is ON and the NMOS transistor MN3 is OFF. The output node OUT is ‘H’ and the inverted output node OUTB is ‘L’. Accordingly, the NMOS transistors MN2, MN5 are ON and the NMOS transistors MN1, MN4 are OFF. The node ND3 is ‘L’ according to the NMOS transistor NM0 being ON and the NMOS transistor MN4 being OFF. The node ND4 is ‘Hd’ according to the NMOS transistor MN5 being ON.

Here, ‘Hd’ of the node ND4 is strictly a potential depending on a magnitude relationship between Vtp and Vtn. In other words, ‘Hd’ is VDD2−Vtp” in the case of Vtp>Vtn as shown in FIG. 10 but it is “VDD2−Vtn” in the case of Vtp<Vtn. It is noted that, however, ‘Hd’ of the node ND4 is not input to the gate of any MOS transistor among those shown in FIG. 4A, the operation is not influenced regardless of the magnitude relationship between Vtp and Vtn.

The node ND1 is ‘Hd’ according to the NMOS transistor MN4 being OFF. Accordingly, both the PMOS transistors MP0, MP1 fall into the boundary state. The node ND2 is also ‘Hd’ according to the NMOS transistor MN3 being OFF. Accordingly, both the PMOS transistors MP2, MP3 fall into the boundary state.

Description is given now about “Time=1 to 4” in FIG. 4D. The state transition in the period substantially corresponding to the “Time=1 to 4” is shown in an upper part of FIG. 4C. When the input node INT transitions from ‘Hl’ to ‘L’ at “Time=1”, the NMOS transistor NM0 transitions from ON to OFF at “Time=2”. At this point, because the NMOS transistor MN4 is OFF, the node ND3 retains ‘L’.

On the other hand, when the inverted input node INB transitions from ‘L’ to ‘Hl’ at “Time=1”, the NMOS transistor MN3 transitions from OFF to ON at “Time=2”. At the point of the NMOS transistor MN3 turning to be ON, the node ND2 is ‘Hd’ and the NMOS transistor MN5 is ON. Thus, as in the first embodiment, the NMOS transistor MN3 can raise the potential of the node ND2 sufficiently via the NMOS transistor MN5.

When the potential of the nodes ND2, ND4 transitions from ‘Hd’ to ‘Ld’, the PMOS transistors MP2, MP3 transition from the boundary state to ON. At this time, because the PMOS transistor MP2 is driven to be ON at the |Vdrop| amplitude larger than the VDD1 amplitude as in the first embodiment, it is possible to sufficiently raise the potential of the inverted output node OUTB.

Description follows below about “Time=5 to 8” in FIG. 4D. The state transition in the period substantially corresponding to the “Time=5 to 8” is shown in a lower part of FIG. 4C. When the inverted output node OUTB is raised from ‘L’ and its potential increases to Vtn or higher at “Time=5”, the NMOS transistor MN1 then transitions from OFF to ON and the output node OUT is also falls from ‘H’ at “Time=6”. Moreover, the NMOS transistor MN4 also transitions from OFF to ON at a timing equivalent to the transition timing of the NMOS transistor MN1 at “Time=6”.

Here, the reason why the NMOS transistor MN4 is transitioned to ON is that the state of the NMOS transistor MN4 when the input signal INT is transitioned from ‘L’ to ‘Hl’ needs to be kept similar to the state of the NMOS transistor MN5 described with reference to “Time=1 to 4” regardless of the through current. In other words, in the steady state in which the NMOS transistor NM0 is turned OFF, the NMOS transistor MN4 needs to be ON, or else it is not possible to lower the potential of the node ND1 when the NMOS transistor NM0 transitions from OFF to ON.

When the NMOS transistor MN4 is turned ON, the node ND3 and the node ND1 are energized. At the time of the energization, the node ND1 is ‘Hd’ and the node ND3 is ‘L’, and thus the potential of the node ND3 is raised and the potential of the node ND1 is temporarily reduced. In connection with the fall of the potential of the node ND1, the PMOS transistors MP0, MP1 also temporarily transition from the boundary state to ON. As a result, it is concerned that the PMOS transistor MP1 may prevent the fall of the output node OUT by the NMOS transistor MN1.

However, because the potential of the node ND1 is reduced by an amount corresponding to the charge of the node ND3, the reduced amount is small enough. Moreover, because the potential of the node ND1 returns to ‘Hd’ after temporarily reduced from ‘Hd’, the time period during which the potential is reduced is also short enough. Therefore, even with the short period, it is possible to keep a state in which Ids of the NMOS transistor MN1 is higher than Ids of the PMOS transistor MP1, and thus the prevention of fall of the output node OUT is not a significant problem.

When the output node OUT falls below Vtn, the NMOS transistor MN2 transitions from ON to OFF and the inverted output node OUTB rests at ‘H’. Furthermore, at the timing of the output node OUT falling below Vtn, the NMOS transistor MN5 also transitions from ON to OFF. As a result, the node ND2 and the node ND4 are disconnected and the through current in the amplitude amplifying circuit AMPb3 is blocked. Then the output node OUT rests at ‘L’ at “Time=8”, where the transition operation of the output node OUT and the inverted output node OUTB is completed.

In response to the NMOS transistor MN5 being turned OFF at “Time=7”, the node ND4 transitions from ‘Ld’ to ‘L’ in association with the NMOS transistor MN3 being turned ON and the node ND2 transitions from ‘Ld’ to ‘Hd’ at “Time=8”. The PMOS transistors MP2, MP3 transition from ON to the boundary state in association with the transition of the node ND2. It is noted that, because the NMOS transistor MN2 is OFF, ‘H’ of the inverted output node OUTB is retained even when the PMOS transistor MP2 transitions to the boundary state.

Through these transitions, at “Time=9”, the steady state is achieved where the input signal INT is ‘L’. The steady state where the input signal INT is ‘L’ is, as in the first embodiment, a state in which one state is exchanged by the other state in a symmetric relation thereto shown in FIG. 4B. At the same time, the state of the NMOS transistor MN4 just added is exchanged by the state of the NMOS transistor MN5. Moreover, contrary to “Time=0 to 9” in FIG. 4D, “Time=10 to 19” in FIG. 4E shows the transition state of the input node INT transitioning from ‘L’ to ‘Hl’. The transition state in FIG. 4E is also a state in which one state is exchanged by the other state in a symmetric relation thereto shown in FIG. 4D.

### <<Major Effect of Third Embodiment>>

As described above, the level shift circuit according to the third embodiment includes switches that perform the following operations. First, in the steady state, a switch (for example, MN4 in FIG. 4B) coupled to an input transistor in the ON state (MN0) is OFF and a switch (MN5) coupled to an input transistor in the OFF state (MN3) is turned ON. Once the input transistor (MN3) in the OFF state transitions to ON, the switch coupled to it transitions to OFF when an output signal (OUT, OUTB) transitions later. On the other hand, once the input transistor (MN0) in the ON state transitions to OFF, the switch (MN4) coupled to it transitions to ON when the output signal (OUT, OUTB) transitions later.

Use of the level shift circuit including such switches makes it possible to reduce the power consumption in the steady state in addition to the effect similar to that in the first embodiment. Thus, by reducing the internal power supply potential VDD1, the power consumption of the internal logic circuit ILOG in FIG. 1 can be reduced, and also the level shift operation with a predetermined performance is enabled at low power consumption in the level shift circuit.

### Fourth Embodiment

### <<Configuration of Level Shift Circuit (Fourth Embodiment)>>

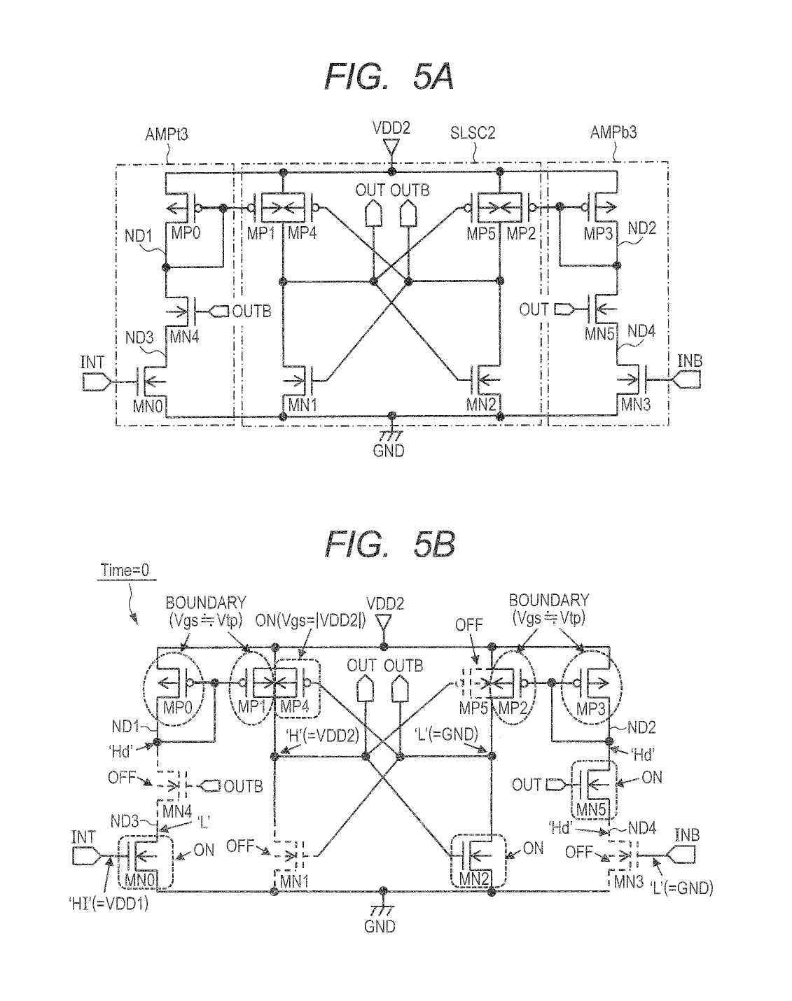

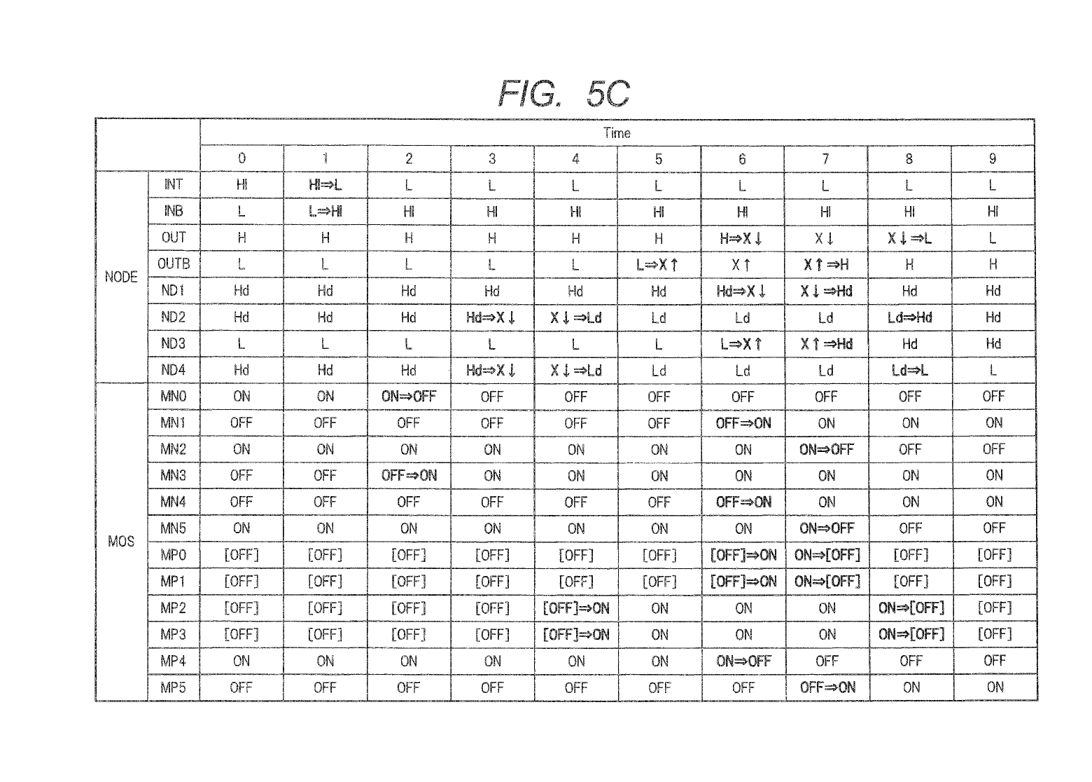

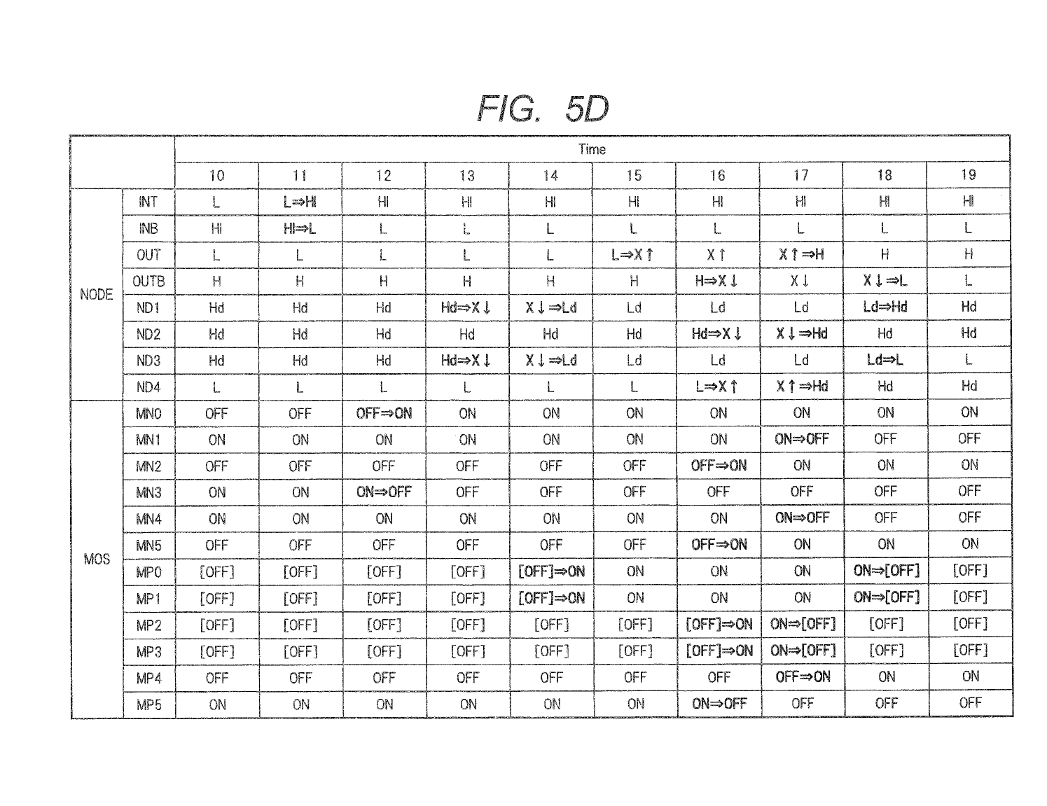

FIG. 5A is a circuit diagram showing an exemplary configuration of a level shift circuit according to a fourth embodiment of the invention. The level shift circuit shown in FIG. 5A includes a sublevel shift circuit SLSC2 that is different from that in the level shift circuit shown in FIG. 4A. The sublevel shift circuit SLSC2 additionally includes PMOS transistors MP4, MP5. The PMOS transistor MP4 is coupled in parallel with the PMOS transistor MP1, and its gate is driven by the inverted output signal (OUTB). The PMOS transistor MP5 is coupled in parallel with the PMOS transistor MP2, and its gate is driven by the output signal (OUT).

The PMOS transistor MP4 configures the CMOS inverter circuit with the NMOS transistor MN1 and outputs the output signal (OUT) in response to the inverted output signal (OUTB). On the other hand, the PMOS transistor MP5 configures the CMOS inverter circuit with the NMOS transistor MN2 and outputs the inverted output signal (OUTB) in response to the output signal (OUT).

With the configuration of the third embodiment described above, the operational state may become unstable. Specifically, for example, as shown in FIG. 4B, ‘H’ of the output node OUT is retained by the PMOS transistor MP1 in the boundary state and the NMOS transistor MN1 in the OFF state, in a substantially floating form. As a result, it may be difficult to keep sufficient stability of the potential of the output node OUT (inverted output node OUTB).

Furthermore, for example, during the transition period, as shown in FIG. 4CC, the PMOS transistor MP2 transitions from the boundary state to the ON state and from the ON state to the boundary state, and the inverted output node OUTB is transitioned to ‘H’ generally during the ON period. If the ON period is reduced (for example, if the output node OUT transitions to ‘L’ faster), it may take longer time for the inverted output node OUTB to transition to ‘H’. This is why the PMOS transistors MP4, MP5 are provided.

### <<Operation of Level Shift Circuit (Fourth Embodiment)>>

FIG. 5B is a circuit diagram showing an exemplary state of each node and each transistor in the steady state in FIG. 5A. FIG. 5C is a transition diagram summarizing one example of a time-series state transition of each node and each transistor associated with transition of an input signal in FIG. 5A, and FIG. 5D is a transition diagram summarizing one example of a time-series state transition of each node and each transistor associated with the transition of the input signal in a direction opposite from FIG. 5C.

Shown at “Time=0” in FIGS. 5B and 5C is the state of each node and each transistor when the input node INT is ‘Hl’. The state in FIG. 5B is different from the state in FIG. 4B in that the additional PMOS transistor MP4 is turned ON and the additional PMOS transistor MP5 is turned OFF. The state transitions shown in FIGS. 5C and 5D are the same as the state transitions shown in FIGS. 4D and 4E except that the states of the PMOS transistors MP4, MP5 are added.

To explain it briefly, at “Time=1 to 4” in FIG. 5D, the inverted output node OUTB is raised in the same manner as “Time=1 to 4” in FIG. 4D and as in the upper part of FIG. 4C. In response to this, at “Time=6” in FIG. 5C, the NMOS transistor MN1 transitions from OFF to ON and the PMOS transistor MP4 contrarily transitions from ON to OFF. As a result, the output node OUT is dropped via the NMOS transistor MN1.

When the output node OUT is dropped, at “Time=7” in FIG. 5C, the NMOS transistor MN2 transitions from ON to OFF, and the PMOS transistor MP5 contrarily transitions from OFF to ON. As a result, in addition to the PMOS transistor MP2 that is already turned ON, the inverted output node OUTB is raised via the PMOS transistor MP5 and rests at ‘H’. Thus, even when the PMOS transistor MP2 then transitions from ON to the boundary state at “Time=8” in FIG. 5C in the same manner as in the lower part of FIG. 4C, ‘H’ of the inverted output node OUTB is stably retained by the PMOS transistor MP5.

### <<Major Effect of Fourth Embodiment>>

As described above, by using the level shift circuit according to the fourth embodiment, it is possible not only to obtain the effect similar to that in the third embodiment but also to stabilize the operational state better than the case of the third embodiment. Specifically, for example, in the steady state, it is possible to stably retain ‘H’ of the output node OUT or the inverted output node by the PMOS transistor MP4 or the PMOS transistor MP5.

Furthermore, the NMOS transistors MN1, MN2 and the PMOS transistors MP4, MP5 function as, so to say, CMOS-type sense amplifier circuits. Thus, for example, when the inverted input node INB transitions to ‘Hl’ in FIG. 5B, once the transistor MP2 drives the NMOS transistor MN1 to be ON, the output node OUT and the inverted output node OUTB quickly and stably transitions to ‘L’ and ‘H’ respectively by the action of the sense amplifier circuit.

### Fifth Embodiment

### <<Configuration of Level Shift Circuit (Fifth Embodiment)>>

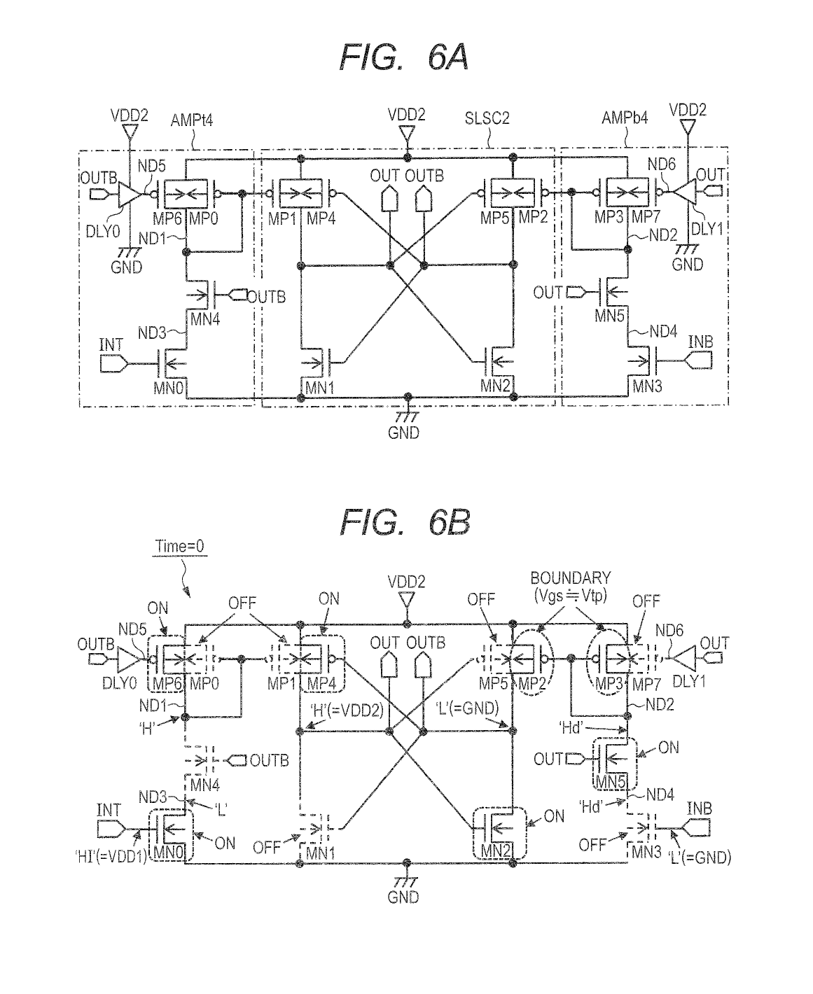

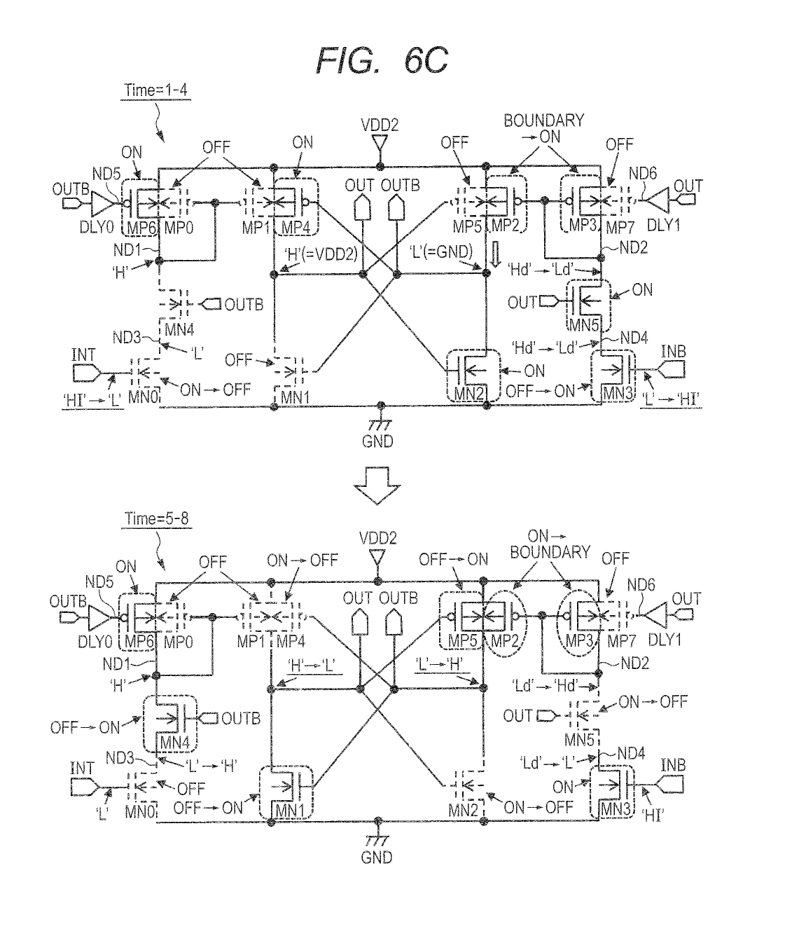

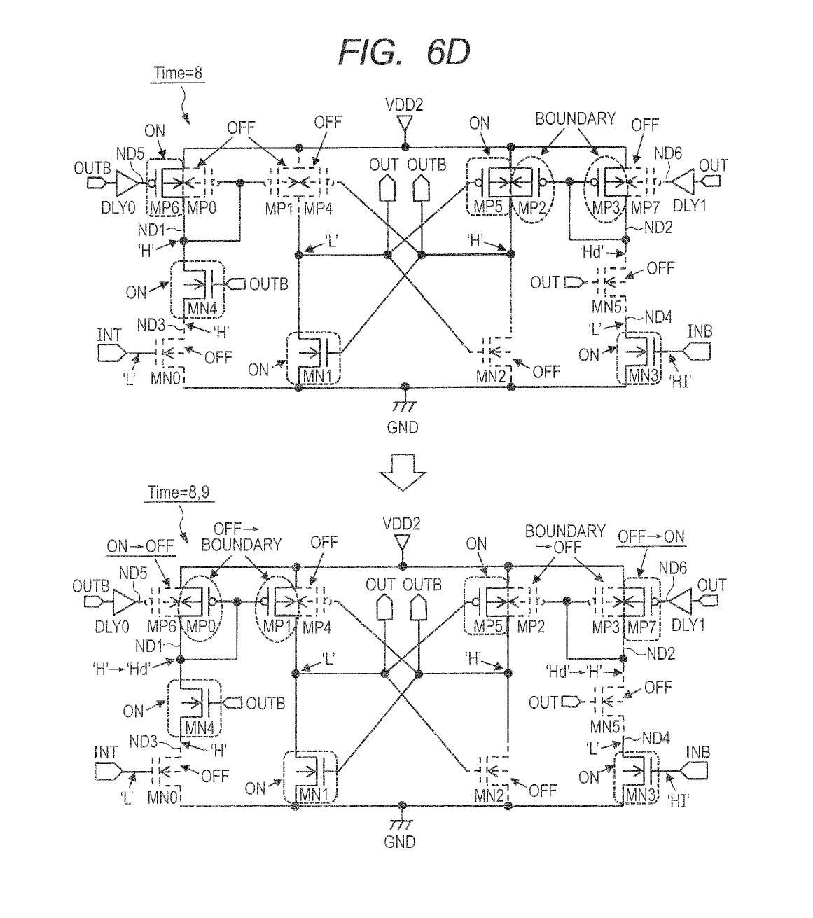

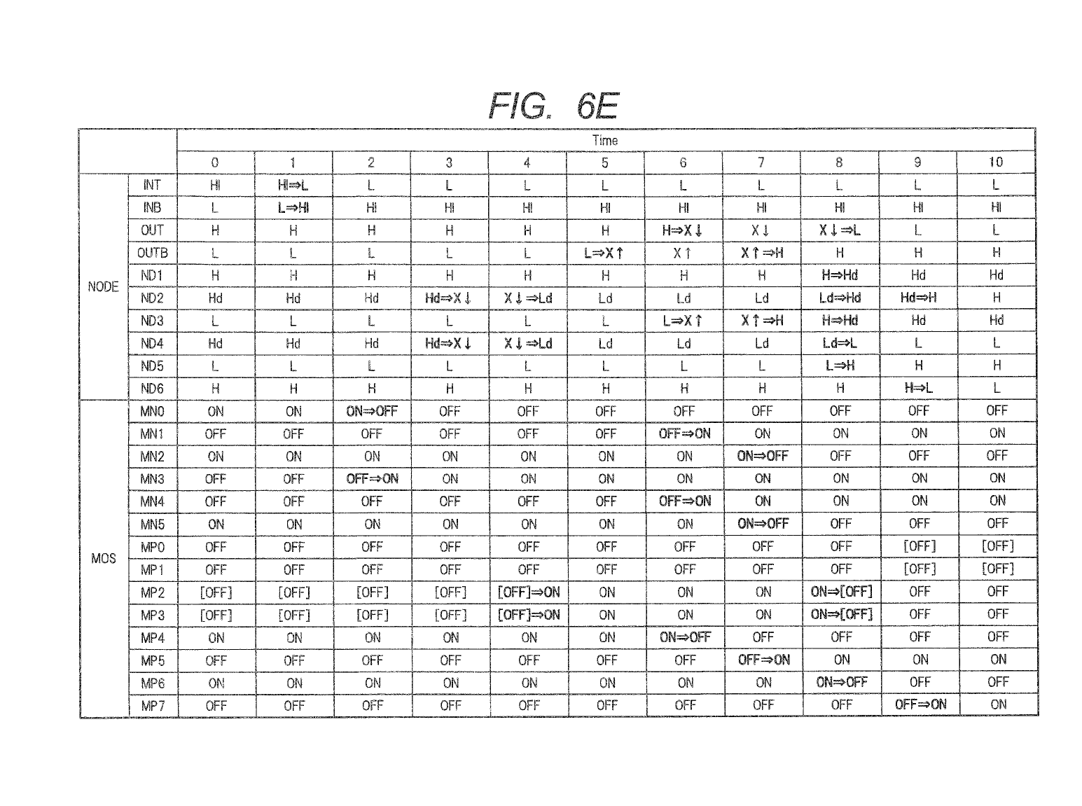

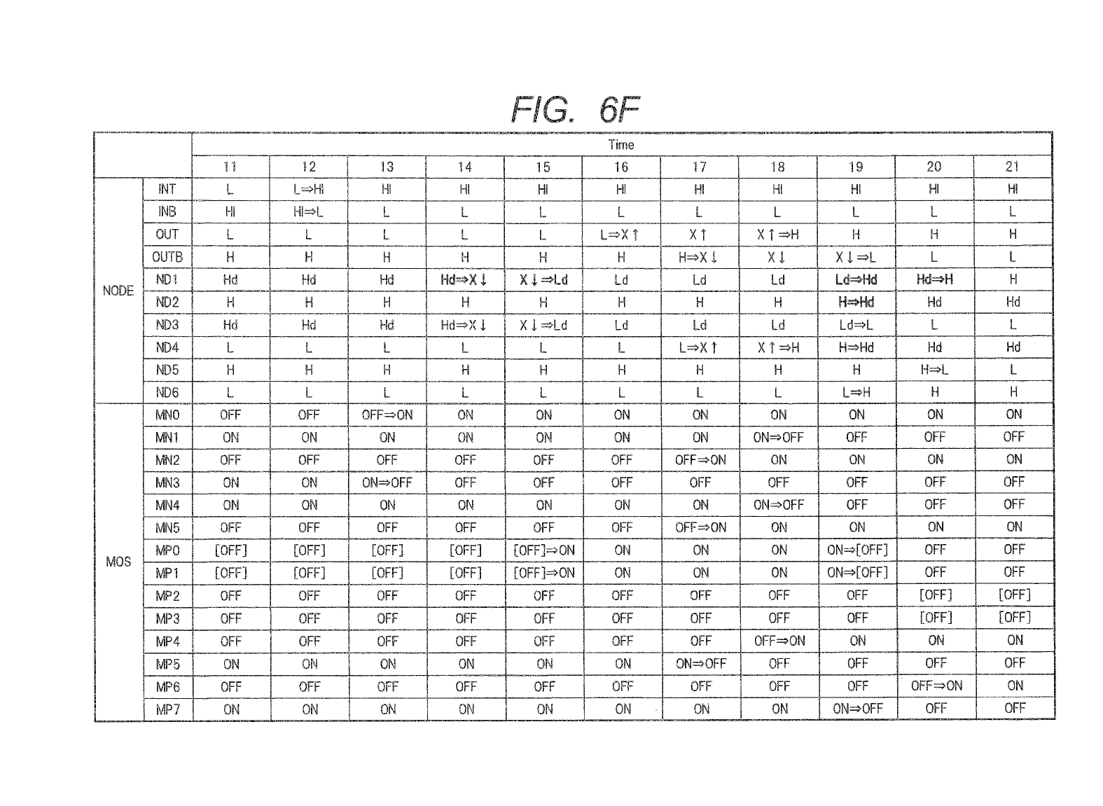

FIG. 6A is a circuit diagram showing an exemplary configuration of a level shift circuit according to a fifth embodiment of the invention. The level shift circuit shown in FIG. 6A includes amplitude amplifying circuits AMPt4, AMPb4 different from the e level shift circuits shown in FIG. 5A. The amplitude amplifying circuit AMPt4 additionally includes a PMOS transistor MP6 and a delay circuit DLY0, and the amplitude amplifying circuit AMPb4 additionally includes a PMOS transistor MP7 and a delay circuit DLY1.

The delay circuits DLY0, DLY1 are supplied with the external power supply potential VDD2 and the reference power supply potential GND. The delay circuits DLY0, DLY1 output a control signal (signal from node ND6) generated by delaying the output signal (OUT) and an inverted control signal (signal from node ND5) having a polarity opposite from the control signal. In this example, there are provided the delay circuit DLY0 that delays the inverted output signal (OUTB) and outputs the inverted control signal (signal from the node ND5) and the delay circuit DLY1 that delays the output signal (OUT) and outputs the control signal (signal from the node ND6). The delay circuits DLY0, DLY1 are typically configured by a plurality of stages of CMOS inverter circuits or the like. However, it should be noted that the delay circuit is not specifically limited to such a configuration but may be any configuration capable of outputting the control signal and the inverted control signal of the VDD2 amplitude.

The PMOS transistor MP6 is coupled in parallel with the PMOS transistor MP0, and its gate is driven by the inverted control signal signal from the node ND5). The PMOS transistor MP7 is coupled in parallel with the PMOS transistor MP3, and its gate is driven by the control signal (signal from the node ND6). The delay circuit DLY0 plays a role of transitioning the PMOS transistor MP6 to OFF or ON after a predetermined period has passed in response to transition of the NMOS transistor MN4 to ON or OFF. Similarly, the delay circuit DLY1 plays a role of transitioning PMOS transistor MP7 to OFF or ON after a predetermined period has passed in response to transition of the NMOS transistor MN5 to ON or OFF.

### <<Operation of Level Shift Circuit (Fifth Embodiment)>>

FIG. 6B is a circuit diagram showing an exemplary state of each node and each transistor in the steady state in FIG. 6A. FIG. 6C is a circuit diagram showing an example of a state transition of each node and each transistor during a transition period in FIG. 6A, and FIG. 6D is a circuit diagram showing an example of a state transition of each node and each transistor following FIG. 6C. FIG. 6E is a transition diagram summarizing one example of a time-series state transition of each node and each transistor associated with transition of an input signal in FIG. 6A, and FIG. 6F is a transition diagram summarizing one example of a time-series state transition of each node and each transistor associated with the transition of the input signal in a direction opposite from FIG. 6E.

During the initial period (Time=0) (in other words, steady state) in FIG. 6E, as shown in FIG. 6B, the input node INT is ‘Hl’, the inverted input node INB is ‘L’, the output node OUT is ‘H’, and the inverted output node OUTB is ‘L’. Accordingly, as in the case of FIG. 5B, the NMOS transistors MN0, MN2, NM5 are ON, the NMOS transistors MN3, MN1, MN4 are OFF, the PMOS transistor MP4 is ON, and the PMOS transistor MP5 is OFF. Furthermore, the additional PMOS transistor MP6 is turned ON in association with the node ND5 being ‘L’, and the additional PMOS transistor MP7 is turned OFF in association with the node ND6 being ‘H’.

According to the PMOS transistor MP6 in the ON state and the NMOS transistor MN4 in the OFF state, the node ND1 falls into ‘H’ and the PMOS transistors MP0, MP1 fall into OFF instead of the boundary state unlike the case of FIG. 5B. On the other hand, because the PMOS transistor MP7 is OFF, the node ND2 falls into ‘Hd’ and the PMOS transistors MP2, MP3 fall into the boundary state as in the case of FIG. 5B. Furthermore, as in the case of FIG. 5B, the node ND3 is ‘L’ and the node ND4 is ‘Hd’.

Now, explanation is given about “Time=1 to 4” in FIG. 6E. The state transition in the period substantially corresponding to the “Time=1 to 4” is shown in the upper part of FIG. 6C. When the input node INT transitions from ‘Hl’ to ‘L’ at the “Time=1”, the NMOS transistor NM0 transitions from OFF to ON at the “Time=2”. At this time, because the NMOS transistor MN4 is OFF, the node ND3 retains ‘L’ and the node ND1 retains ‘H’ via the PMOS transistor MP6 in the ON state.

On the other hand, when the inverted input node INB transitions from ‘L’ to ‘Hl’ at “Time=1”, the NMOS transistor MN3 transitions from OFF to ON at “Time=2”. At the timing when the NMOS transistor MN3 transitions to ON, the node ND2 is ‘Hd’ and the NMOS transistor MN5 is ON. Furthermore, the PMOS transistor MP7 is OFF. Thus, the NMOS transistor MN3 can sufficiently lower the potential of the node ND2 via the NMOS transistor MN5 as in the case of the first embodiment.

When the potentials of the nodes ND2, ND4 transition from ‘Hd’ to ‘Ld’, the PMOS transistors MP2, MP3 transition from the boundary state to ON. At this time, as in the case of the first embodiment, because the PMOS transistor MP2 is driven to be ON by the |Vdrop| amplitude larger than the VDD1 amplitude, it is possible to sufficiently raise the potential of the inverted output node OUTB.

Next, explanation is given about “Time=5 to 8” in FIG. 6E. The state transition in the period substantially corresponding to the “Time=5 to 8” is shown in the lower part of FIG. 6C. At “Time=5”, the inverted output node OUTB is raised from ‘L’ and increases beyond Vtn and ‘Hd’. Accordingly, at “Time=6”, the NMOS transistor MN1 transitions from OFF to ON and the PMOS transistor MP4 transitions from ON to OFF, while the output node OUT is dropped from ‘H’. Moreover, at the same timing as the transition of the NMOS transistor MN1 at “Time=6”, the NMOS transistor MN4 also transitions from OFF to ON.

When the NMOS transistor MN4 is turned ON, the node ND3 and the node ND1 are energized. At the time of the energization, the node ND1 is ‘H’ and the node ND3 is ‘L’, and thus the potential of the node ND3 is raised. However, unlike the case of the lower part of FIG. 4C described above, the node ND1 retains ‘H’ in association with the PMOS transistor MP6 being turned ON. This can prevent the temporary drop of the potential of the node ND1 as shown in the lower part of FIG. 4C, and thus prevent the temporary ON state of the PMOS transistors MP0, MP1 (i.e. prevention of drop operation of the output node OUT).

When the output node OUT is lowered below Vtn via ‘Hd’ at “Time=7”, the PMOS transistor MP5 transitions from OFF to ON and also the NMOS transistor MN2 transitions from ON to OFF. As a result, the inverted output node OUTB rests at ‘H’. In addition, the NMOS transistor MN5 also transitions from ON to OFF at a timing of the output node OUT being dropped below Vtn. As a result, the node ND2 and the node ND4 are disconnected and the through current in the amplitude amplifying circuit AMPb4 is blocked. Then the output node OUT rests at ‘L’ at “Time=8”, where the transition operation of the output node OUT and the inverted output node OUTB is completed.

In response to the NMOS transistor MN5 being turned OFF at “Time=7”, the node ND4 transitions from ‘Ld’ to ‘L’ in association with the NMOS transistor MN3 being turned ON and the node ND2 transitions from ‘Ld’ to ‘Hd’ at “Time=8”. The PMOS transistors MP2, MP3 transition from ON to the boundary state in association with the transition of the node ND2. Here, because the PMOS transistor MP5 is ON and the NMOS transistor MN2 is OFF, ‘H’ of the inverted output node OUTB is retained even when the PMOS transistor MP2 transitions to the boundary state.

Description follows below about “Time=8, 9” in FIG. 6E. The state transition in the period substantially corresponding to the “Time=8, 9” is shown in FIG. 6D. The upper part of FIG. 6D shows the final state of the lower part of FIG. 6C. Starting from this state, in the lower part of FIG. 6D, the PMOS transistor MP6 transitions from ON to OFF via the delay circuit DLY0 (“Time=8”), and the PMOS transistor MP7 transitions from OFF to ON via the delay circuit DLY1 (“Time=9”).

When the PMOS transistor MP6 transitions to OFF, the node ND1 falls into a floating state to either retain ‘H’ or drops to ‘Hd’ due to leakage or the like. When dropping to ‘Hd’, the PMOS transistors MP0, MP1 transitions from OFF to the boundary state, and therefore the node ND1 will not be reduced below ‘Hd’. At “Time=8” in FIG. 6E, the node ND1 is shown to be ‘Hd’, but there will be no specific influence on the operation even if it is ‘H’ instead of ‘Hd’. In other words, the difference is, for example, in the lower part of FIG. 6D, whether the PMOS transistor MP0 to be the load circuit of the NMOS transistor NM0 is in the boundary state or in the OFF state at the later timing the input node INT transitions to ‘Hl’. In either case, the NMOS transistor NM0 can easily lower the potential of the node ND1.

On the other hand, when the PMOS transistor MP7 transitions to ON, the node ND2 transitions from ‘Hd’ to ‘H’ at “Time=9”. In response to this, the PMOS transistors MP2, MP3 transition from the boundary state to OFF. Through these transitions, at “Time=10”, the steady state is achieved where the input signal INT is ‘L’. It is noted that the steady state that is the final state of FIG. 6D and the steady state shown in FIG. 6B are in a symmetric relation.

Contrary to “Time=0 to 10” in FIG. 6E, “Time=11 to 21” in FIG. 6F shows the transition state of the input node INT transitioning from ‘L’ to ‘Hl’. The transition state in FIG. 6F is a state in which one state is exchanged by the other state in a symmetric relation thereto shown in FIG. 6E, as in the prior embodiments. At the same time, the states of the node ND5 and the PMOS transistor MP6 added in this embodiment are exchanged by the states of the node ND6 and the PMOS transistor MP7.

### <<Major Effect of Fifth Embodiment>>

In the first to fourth embodiments described above, it is necessary to set the driving ability of the PMOS transistors MP0, MP3 relatively lower (in other words, set the ON resistance relatively higher). This is done to facilitate drop of the potential of the nodes ND1, ND2 by the NMOS transistors NM0, MN3 and also to set the voltage amplitude of the nodes ND1, ND2 larger than the VDD1 amplitude, as mentioned with reference to the first embodiment and the like.

It should be noted that there may be an adverse effect of requiring some time to return the potential of the nodes ND1, ND2 from the lower state to ‘Hd’. It is assumed as an example that the input node INT transitions to ‘Hl’ before the node ND2 returns from ‘Ld’ to ‘Hd’ (and accordingly with the PMOS transistor MP2 being turned ON) in the lower part of FIG. 4C in association with a high-speed input signal (INB). In this case, the transition of the inverted output node OUTB to ‘L’ delays to make the operational state unstable, which may cause, for example, a jitter depending on the data pattern of the input signal (INT).

And so, using the level shift circuit according to the fifth embodiment, as shown in the lower part of FIG. 6D, it is possible to quickly return the node ND2 to ‘H’ by the PMOS transistor MP7 of the VDD2 amplitude after the output signal (OUT) transitioned. Moreover, as mentioned with reference to the lower part of FIG. 6C, it is also possible to prevent the temporary drop of the potential of the node ND1 by the delay circuit DLY0 and the PMOS transistor MP6.

Furthermore, it is ensured to prevent an event in which the PMOS transistor MP7 should be turned ON in such a state as shown in the upper part of FIG. 6C, for example. In other words, if the delay circuit DLY1 is not provided, the NMOS transistor MN5 may be turned OFF after the PMOS transistor MP7 is turned ON in response to the output signal (OUT). In such a case, during the period in which both transistors (MN5, MP7) are turned ON, the drop operation of the potential of the node ND2 by the NMOS transistor MN3 will be seriously prevented. On the other hand, when the delay circuit DLY1 is provided, the load circuit when the NMOS transistor MN3 performs the drop operation is always the PMOS transistor MP3 alone.

From the above, use of the level shift circuit according to the fifth embodiment makes it possible not only to obtain the effect similar to that in the fourth embodiment but also to further stabilize the operational state compared with the case in the fourth embodiment. As a result, it is especially possible to improve the operation speed.

### Sixth Embodiment

### <<Configuration of Level Shift Circuit (Sixth Embodiment)>>

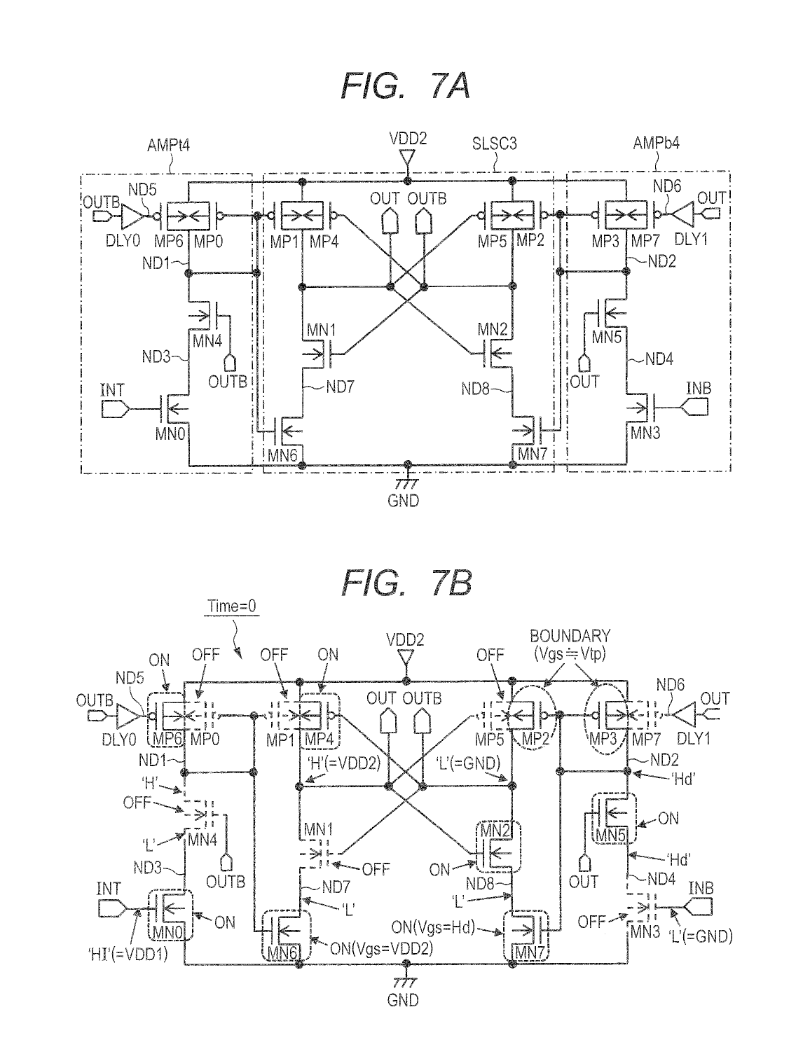

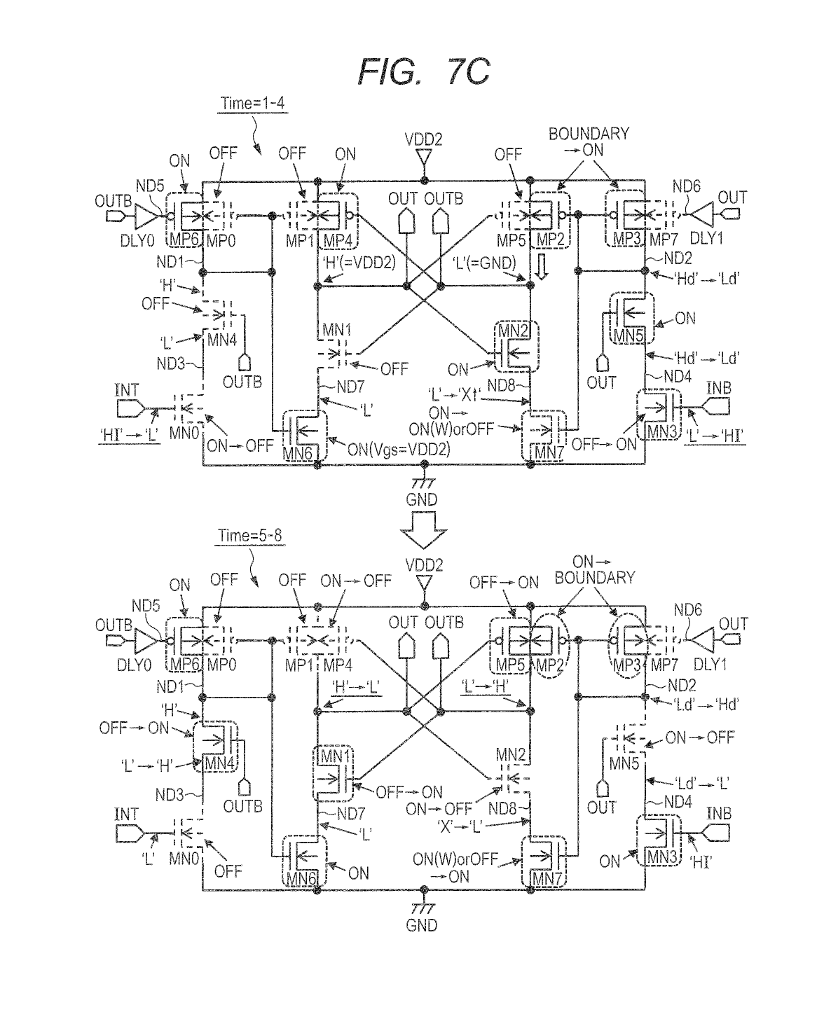

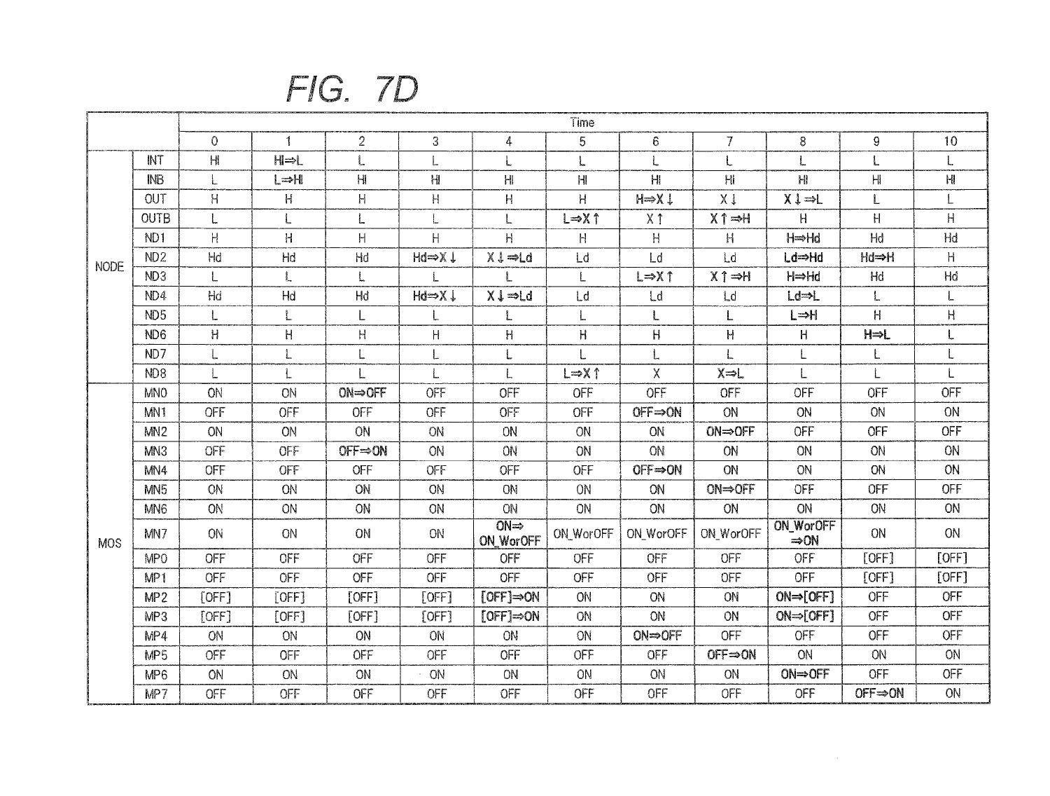

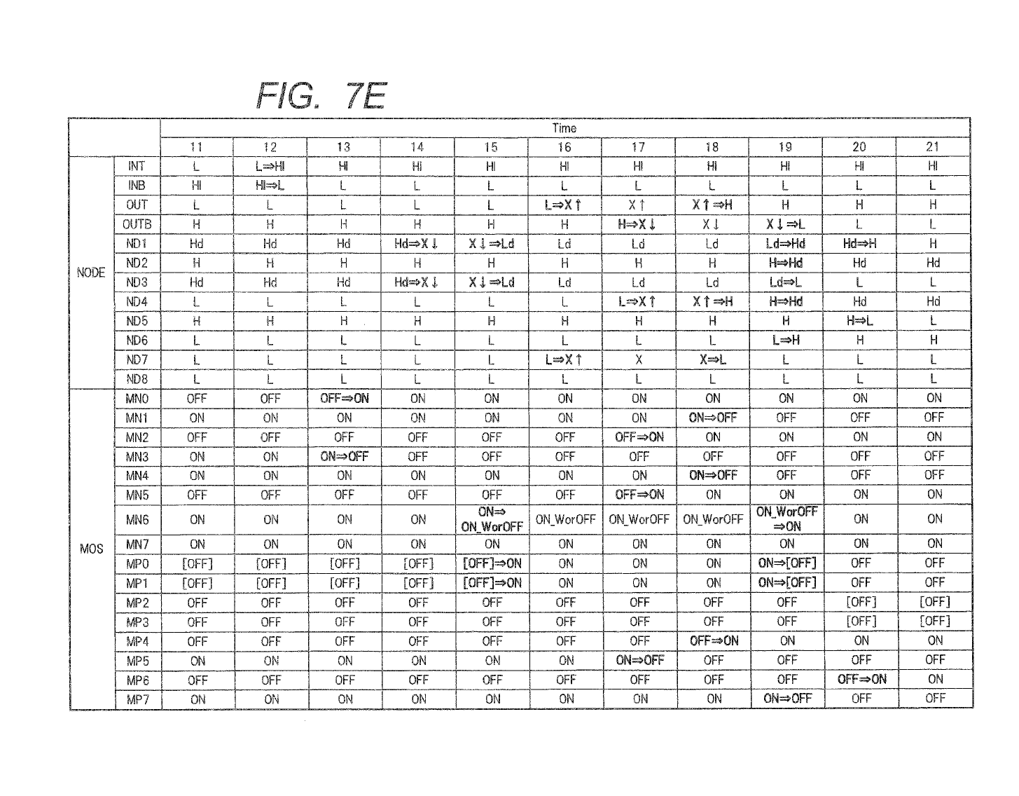

FIG. 7A is a circuit diagram showing an exemplary configuration of a level shift circuit according to a sixth embodiment of the invention. The level shift circuit shown in FIG. 7A includes a sublevel shift circuit SLSC3 that is different from that in the level shift circuit shown in FIG. 6A. The sublevel shift circuit SLSC3 additionally includes NMOS transistors MN6, MN7. The NMOS transistor MN6 is provided with a drain-source path between the NMOS transistor MN1 and the reference power supply potential GND, and the NMOS transistor MN7 is provided with a drain-source path between the NMOS transistor MN2 and the reference power supply potential GND.

In the first to fifth embodiments described above, for example in the upper part of FIG. 6C, when the PMOS transistor MP2 raises the potential of the inverted output node OUTB, the NMOS transistor MN2 is driven to be ON by the VDD2 amplitude. As described above, because the PMOS transistor MP2 is driven to be ON by the voltage amplitude larger than the VDD1 amplitude, it is possible to sufficiently raise the potential of the inverted output node OUTB. In addition, by lowering the driving ability of the NMOS transistor MN2, it is made possible to raise the potential of the inverted output node OUTB more easily. Therefore, the NMOS transistors MN6, MN7 are provided.

In the example shown in FIG. 7A, the gate of the NMOS transistor MN6 is driven by the node ND1 and the node of the NMOS transistor MN7 is driven by the node ND2. In this manner, during the period in which the PMOS transistor MP2 makes the inverted output signal (OUTB) transition to the external power supply potential VDD2, schematically the NMOS transistor MN7 is driven to be either ON or OFF and the NMOS transistor MN6 is driven to be ON by the voltage amplitude smaller than the VDD2 amplitude. To the contrary, during the period in which the PMOS transistor MP1 makes the output signal (OUT) transition to the external power supply potential VDD2, the NMOS transistor MN6 is driven to be either ON or OFF and the NMOS transistor MN7 is driven to be ON by the voltage amplitude smaller than the external power supply potential VDD2.

### <<Operation of Level Shift Circuit (Sixth Embodiment)>>

FIG. 7B is a circuit diagram showing an exemplary state of each node and each transistor in the steady state in FIG. 7A, and FIG. 7C is a circuit diagram showing an example of a state transition of each node and each transistor during a transition period in FIG. 7A. FIG. 7D is a transition diagram summarizing one example of a time-series state transition of each node and each transistor associated with transition of an input signal in FIG. 7A, and FIG. 7E is a transition diagram summarizing one example of a time-series state transition of each node and each transistor associated with the transition of the input signal in a direction opposite from FIG. 7D.

Shown at “Time=0” in FIGS. 7B and 7D are the steady states when the input node INT is ‘Hl’. The state shown in FIG. 7B is the same as that shown in FIG. 6B except for the states of the NMOS transistors MN6, MN7 and states of nodes ND7, ND8 added thereto. The node ND7 is a coupling node of the NMOS transistor MN1 and the NMOS transistor MN6, and the node ND8 is a coupling node of the NMOS transistor MN2 and the NMOS transistor MN7.

As shown in FIG. 7B, the NMOS transistor MN6 is driven to be ON by the VDD2 amplitude in association with ‘H’ of the node ND1. On the other hand, the NMOS transistor MN7 is driven to be ON at the “VDD2−|Vtp|” amplitude in association with ‘Hd’ of the node ND2. Moreover, the nodes ND7, ND8 are both ‘L’. The circuit in such a state is substantially equivalent to the circuit according to the fifth embodiment in which the sources of the NMOS transistors MN1, MN2 are directly coupled to the reference power supply potential GND. Thus, the circuit shown in FIG. 7A operates in the same manner as the circuit shown in FIG. 6A unless the states of the nodes ND1, ND2 change.

Now, explanation is given about “Time=1 to 4” in FIG. 7D. The state transition in the period substantially corresponding to the “Time=1 to 4” is shown in the upper part of FIG. 7C. The state transitions indicated by “Time=1 to 4” in FIG. 7D and in the upper part of FIG. 7C are substantially the same as the state transitions indicated by “Time=1 to 4” in FIG. 6E and in the upper part of FIG. 6C except that the states of the NMOS transistors MN6, MN7 and the nodes ND7, ND8 are added thereto. First, as for the NMOS transistor MN6 and the node ND7, even when the input node INT transitions from ‘Hl’ to ‘L’ at “Time=1”, the node ND1 retains ‘H’ as it is, and therefore they do not change from the steady state shown in FIG. 7B.

On the other hand, as for the NMOS transistor MN7 and the node ND8, when the inverted input node INB transitions from ‘L’ to ‘Hl’ at “Time=1”, the node ND2 transitions from ‘Hd’ to ‘Ld’ at “Time=3,4” as in the case of the upper part of FIG. 6C. Accordingly, the ON state of the NMOS transistor MN7 is weakened and it may be turned OFF in some cases. In FIG. 7D, the weak ON state is indicated by “ON_W”. The potential of the node ND8 is raised from ‘L’ by the NMOS transistor MN7, whereby the input voltage amplitude (=Vgs) of the NMOS transistor MN2 in the ON state becomes smaller than the VDD2 amplitude. As a result, the PMOS transistor MP2 in the ON state can easily raise the potential of the inverted output node OUTB.

Next, explanation is given about “Time=5 to 8” in FIG. 7D. The state transition in the period substantially corresponding to the “Time=5 to 8” is shown in the lower part of FIG. 7C. The state transitions indicated by “Time=5 to 8” in FIG. 7D and in the lower part of FIG. 7C are also substantially the same as the state transitions indicated by “Time=5 to 8” in FIG. 6E and in the lower part of FIG. 6C except that the states of the NMOS transistors MN6, MN7 and the nodes ND7, ND8 are added thereto. First, as for the NMOS transistor MN6 and the node ND7, the node ND1 still retains ‘H’, and therefore the states of the NMOS transistor MN6 and the node ND7 remain the same as in FIG. 7C.

On the other hand, as for the NMOS transistor MN7 and the node ND8, like the case shown in the lower part of FIG. 6C, when the NMOS transistor MN5 transitions from ON to OFF, the node ND2 transitions from ‘Ld’ to ‘Hd’. Accordingly, the NMOS transistor MN7 transitions from the weak ON state or OFF to ON, and the potential of the node ND8 transitions from the raised state to ‘L’. In other words, at this point, the PMOS transistor MP2 has already completed its role of raising the potential of the inverted output node OUTB. Thus, the PMOS transistor MP2 is returned to the boundary state by the node ND2, and the NMOS transistor MN7 is also returned to ON accordingly.

After this, as in the case of FIG. 6D, the PMOS transistor MP6 is turned OFF and the node ND1 transitions from ‘H’ to ‘Hd’. The PMOS transistor MP7 is turned ON and the node ND2 transitions from ‘Hd’ to ‘H’. Accordingly, although their ON power may change more or less, the NMOS transistors MN6, MN7 still retain the strong ON state.

Indicated by “Time=11 to 21” in FIG. 7E is the transition state when the input node INT transitions from ‘L’ to ‘Hl’ contrary to “Time=0 to 10” in FIG. 7D. The transition state shown in FIG. 7E is a state in which one state is exchanged by the other state in a symmetric relation thereto shown in FIG. 7D, as in the prior embodiments. At the same time, the states of the node ND7 and the NMOS transistor MN6 added in this embodiment are exchanged by the states of the node ND8 and the NMOS transistor MN7, respectively.

### <<Major Effect of Sixth Embodiment>>

From the above, use of the level shift circuit according to the sixth embodiment makes it possible not only to obtain the effect similar to that in the fifth embodiment but also to further extend the power supply potential range in which the level shift operation can be performed, compared with the case in the fifth embodiment. Specifically describing, for example, as the internal power supply potential VDD1 decreases, the drive currents (=Ids) of the NMOS transistors NM0, MN3 decrease and the |Vdrop| amplitudes of the nodes ND1, ND2 also decrease. Consequently, the driving abilities of the PMOS transistors MP1, MP2 further decrease compared with the driving abilities of the NMOS transistors MN1, MN2, which may eventually result in an event in which the raising operation of the potential is difficult in the output node OUT and the like. However, use of the level shift circuit according to the sixth embodiment can lower the driving abilities of the NMOS transistors MN1, MN2 when driving the PMOS transistors MP1, MP2, which can avoid such an event.

### Seventh Embodiment

### <<Configuration of Level Shift Circuit (Seventh Embodiment)>>

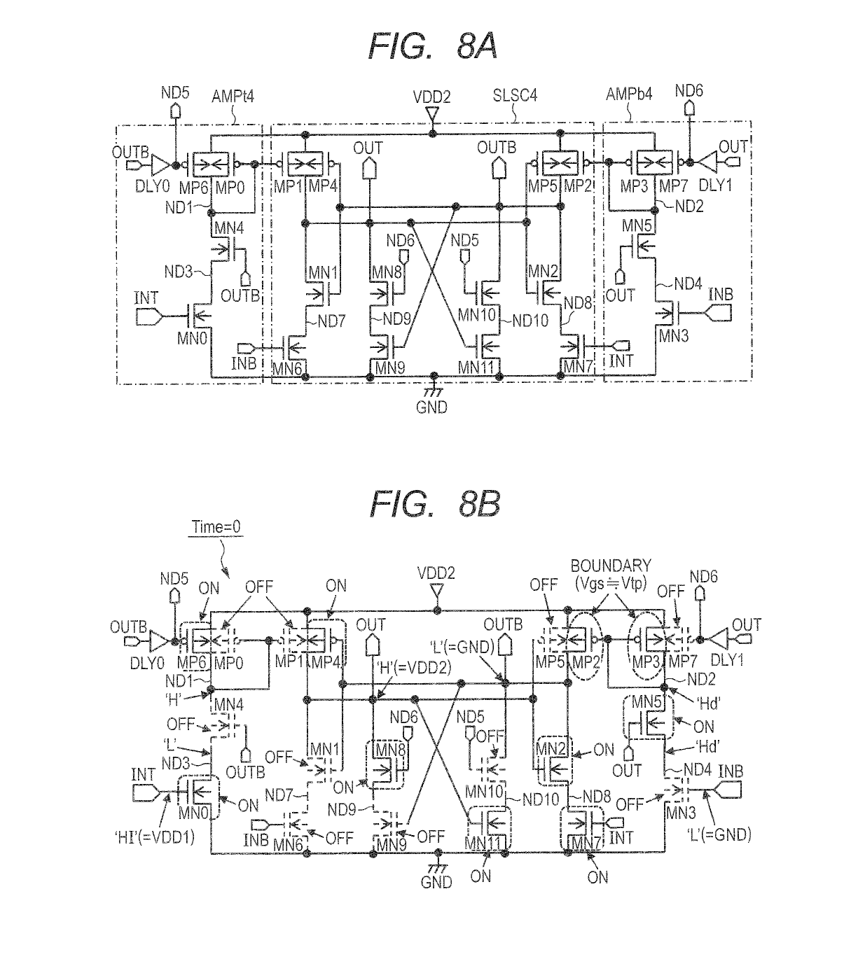

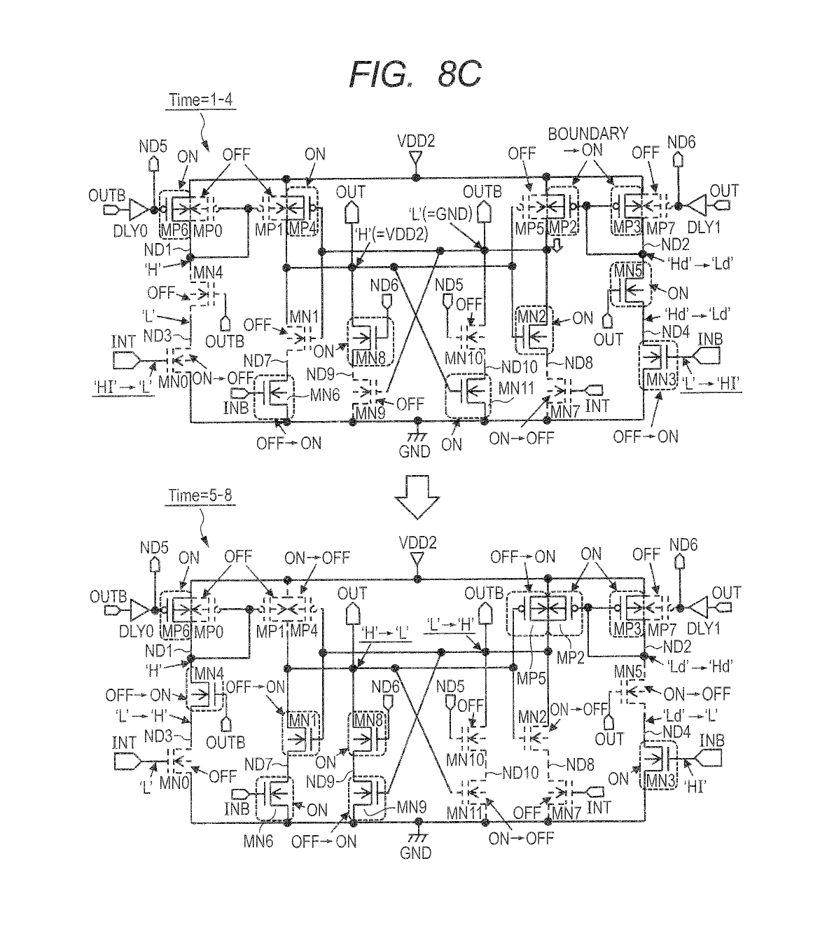

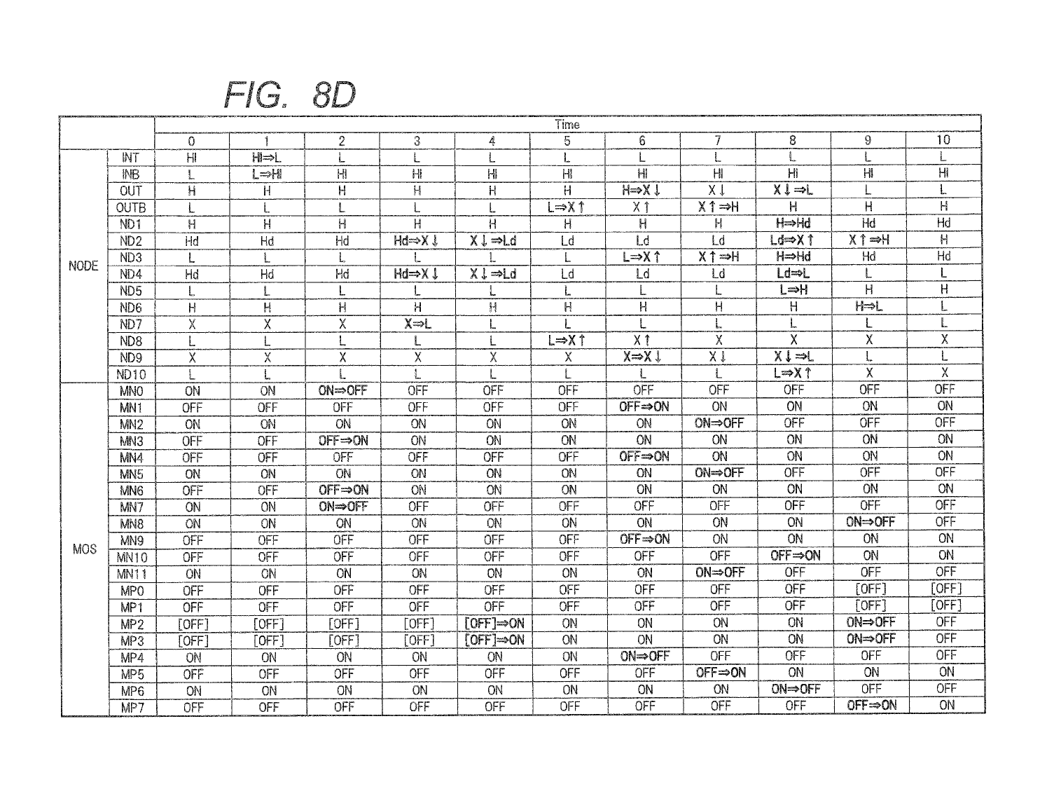

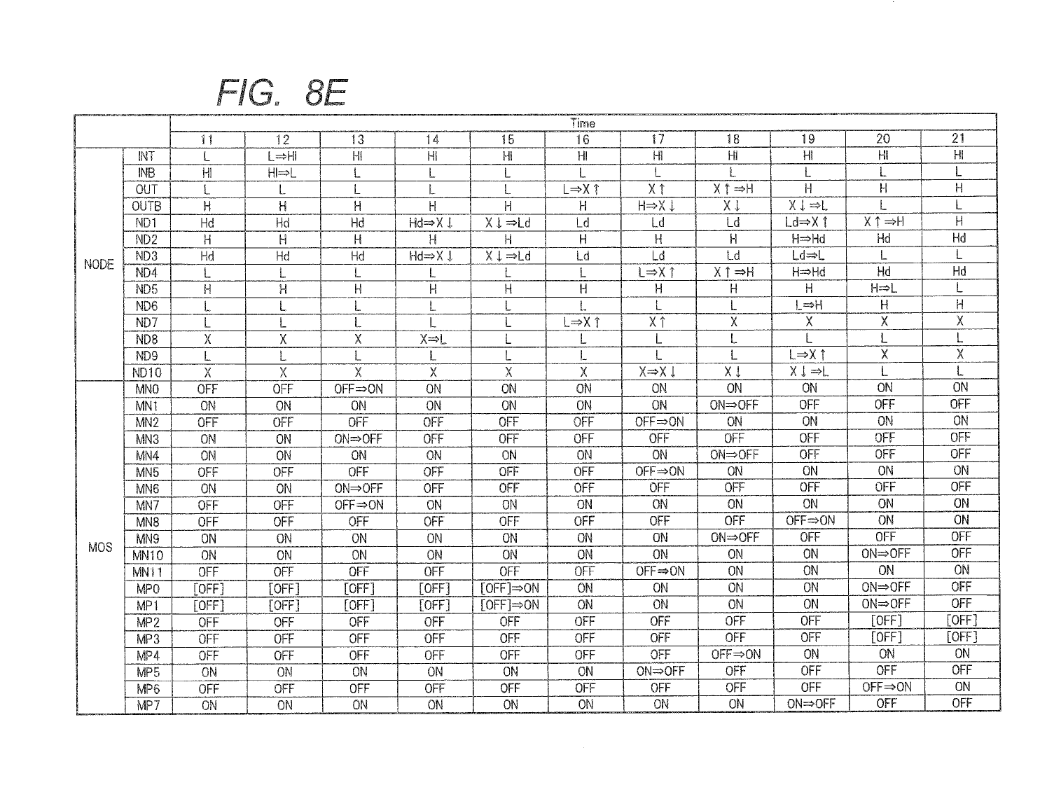

FIG. 8A is a circuit diagram showing an exemplary configuration of a level shift circuit according to a seventh embodiment of the invention. The level shift circuit shown in FIG. 8A includes a sublevel shift circuit SLSC4 that is different from that in the level shift circuit shown in FIG. 7A. The sublevel shift circuit SLSC4 is different from the sublevel shift circuit SLSC3 shown in FIG. 7A in the following two points. The first difference is that the NMOS transistor MN6 is driven not by the node ND1 but by the inverted input signal (INB), while the NMOS transistor MN7 is driven not by the node ND2 but by the input signal (INT).

As the second difference, NMOS transistors MN8 to MN11 are added. The NMOS transistor MN11 is provided with a source-drain path between the reference power supply potential GND and the inverted output node OUTB, and its gate is driven by the output signal (OUT). The NMOS transistor MN9 is provided with a source-drain path between the reference power supply potential GND and the output node OUT, and its gate is driven by the inverted output signal (OUTB). The NMOS transistor MN10 is provided with a drain-source path between the inverted output node OUTB and the NMOS transistor MN11, and its gate is driven by the inverted control signal (signal from the node ND5). The NMOS transistor MN8 is provided with a drain-source path between the output node OUT and the NMOS transistor MN9, and its gate is driven by the control signal (signal from the node ND6).

As in the case of the sixth embodiment, during the period in which the PMOS transistor MP2 makes the inverted output signal (OUTB) transition to the external power supply potential VDD2, the NMOS transistor MN7 plays the role of weakening the driving ability of the NMOS transistor MN2, and the NMOS transistor MN6 is driven to be ON. To the contrary, during the period in which the PMOS transistor MP1 makes the output signal (OUT) transition to the external power supply potential VDD2, the NMOS transistor MN6 plays the role of weakening the driving ability of the NMOS transistor MN1, and the NMOS transistor MN7 is driven to be ON. It is noted however that, unlike the case of the sixth embodiment, the NMOS transistors MN6, MN7 are driven to be OFF instead of the weak ON state in order to weaken the driving abilities of the NMOS transistors MN1, MN2.

On the other hand, for example, during the period in which the PMOS transistor MP2 makes the inverted output signal (OUTB) transition to the external power supply potential VDD2, unlike the sixth embodiment, the NMOS transistor MN6 is turned on not by the VDD2 amplitude but by the VDD1 amplitude. As a result, there is a risk of lowering the ability of dropping the output node OUT to ‘L’ via the NMOS transistors MN1, MN6. Thus, in order to enhance the ability of dropping the output node OUT to ‘L’ and not to prevent the raising ability to ‘H’, there are provided NMOS transistors MN8, MN9.

### <<Operation of Level Shift Circuit (Seventh Embodiment)>>

FIG. 8B is a circuit diagram showing an exemplary state of each node and each transistor in the steady state in FIG. 8A, and FIG. 8C is a circuit diagram showing an example of a state transition of each node and each transistor during a transition period in FIG. 8A. FIG. 8D is a transition diagram summarizing one example of a time-series state transition of each node and each transistor associated with transition of an input signal in FIG. 8A, and FIG. 8E is a transition diagram summarizing one example of a time-series state transition of each node and each transistor associated with the transition of the input signal in a direction opposite from FIG. 8D.

FIG. 8B shows the steady state when the input node INT is ‘Hl’. The state shown in FIG. 8B is the same as that shown in FIG. 7B except for the states of the NMOS transistors MN6 to MN11 and the nodes ND7 to ND10 to be added or altered in this embodiment. The node ND9 is a coupling node of the NMOS transistor MN8 and the NMOS transistor MN9, and the node ND10 is a coupling node of the NMOS transistor MN10 and the NMOS transistor MN11. It should be noted in the seventh embodiment, however, that it is meaningless to strictly define the potentials of the nodes ND7 to ND10, and the detailed description thereof is omitted as is proper.

As shown in FIG. 8B, the NMOS transistor MN6 is driven to be OFF in association with ‘L’ of the inverted input node INB. On the other hand, the NMOS transistor MN7 is driven to be ON at the VDD1 amplitude in association with ‘Hl’ of the input node INT. The NMOS transistor MN8 is turned ON (precisely the boundary state) in association with ‘H’ of the control signal (signal from the node ND6), and the NMOS transistor MN10 is turned OFF in association with ‘L’ of the inverted control signal (signal from the node ND5). The NMOS transistor MN9 is turned OFF in association with ‘L’ of the inverted output node OUTB, and the NMOS transistor MN11 is turned ON in association with ‘H’ of the output node OUT.

Moreover, ‘H’ of the output node OUT is retained by the PMOS transistor MP4 in the ON state, and ‘L’ of the inverted output node OUTB is retained by the NMOS transistors MN2, MN7 in the ON state. At this time, the NMOS transistor MN7 is turned ON with the VDD1 amplitude and has sufficient driving ability to retain ‘L’ of the inverted output node OUTB.

Explanation is given now about “Time=1 to 4” in FIG. 8D. The state transition in the period substantially corresponding to the “Time=1 to 4” is shown in the upper part of FIG. 8C. When the input node INT transitions from ‘Hl’ to ‘L’ at the “Time=1”, the NMOS transistors NM0, MN7 transition from ON to OFF at “Time=2”. Because the NMOS transistor MN4 is OFF and the PMOS transistor MP6 is ON, even when the NMOS transistor NM0 transitions to OFF, the node ND1 still retains ‘H’. On the other hand, when the NMOS transistor MN7 transitions to OFF, the NMOS transistor MN2 is equivalently absent.

When the inverted input node INB transitions from ‘L’ to ‘Hl’ at “Time=1”, the NMOS transistors 3, NB6 transition from OFF to ON at “Time=2”. When the NMOS transistor MN6 transitions to ON, the node ND7 becomes ‘L’. On the other hand, when the NMOS transistor MN3 transitions to ON, as in the prior embodiments, the node ND2 transitions from ‘Hd’ to ‘Ld’ at “Time=3, 4”, and accordingly the PMOS transistors MP2, MP3 transition from the boundary state to ON.

In this manner, the PMOS transistor MP2 raises the potential of the inverted output node OUTB. At this time, the NMOS transistor MN2 in the ON state is equivalently absent in association with the NMOS transistor MN7 being turned OFF, and the NMOS transistor MN11 in the ON state is also equivalently absent in association with the NMOS transistor MN10 being turned OFF. As a result, the PMOS transistor MP2 can easily raise the potential of the inverted output node OUTB.

Next, explanation is given about “Time=5 to 8” in FIG. 8D. The state transition in the period substantially corresponding to the “Time=5 to 8” is shown in the lower part of FIG. 8C. At “Time=5”, the potential of the inverted output node OUTB is raised to reach ‘Hd’ beyond Vtn, and then the NMOS transistor MN1 transitions from OFF to ON and the PMOS transistor MP4 transitions from ON to OFF at “Time=6”. At “Time=6”, the NMOS transistor MN4 also transitions from OFF to ON. Even when the NMOS transistor MN4 transitions to ON, the node ND1 still retains ‘H’, and accordingly the PMOS transistor MP1 also retains the OFF state. As a result, the potential of the output node OUT is dropped via the NMOS transistors MN1, MN6 in the ON state.

Here, because Vgs of the NMOS transistor MN6 is the VDD1 amplitude, it may take some time to reduce the potential of the output node OUT. However, when the potential of the inverted output node OUTB exceeds Vtn at “Time=5”, the NMOS transistor MN9 as well as the NMOS transistor MN1 transitions from OFF to ON at “Time=6”. The NMOS transistor MN9 drops the potential of the output node OUT via the NMOS transistor MN8 that is driven to be ON with the VDD2 amplitude. As a result, it is possible to quickly drop the potential of the output node OUT.

When the potential of the output node OUT lowers below ‘Hd’, the PMOS transistor MP5 transitions from OFF to ON at “Time=7”, and when it further lowers below Vtn, the NMOS transistors MN2, MN11, and MN5 transition from ON to OFF at “Time=7”. Even when the NMOS transistors MN2, MN11 transition to OFF, the NMOS transistors MN7, MN 10 are OFF at this point, and thus no change is caused to the operation. The inverted output node OUTB is fixed to ‘H’ by the PMOS transistor MP5 that is turned ON now.

On the other hand, when the NMOS transistor MN5 transitions to OFF, as in the case of the sixth embodiment, the node ND2 is raised from ‘Ld’ toward ‘Hd’. However, as in the case of the fifth embodiment (i.e. FIG. 6D), during the process, the PMOS transistor MP6 transitions from ON to OFF and the PMOS transistor MP7 transitions from OFF to ON.

As a result, after the state shown in the lower part of FIG. 8C, the node ND1 becomes ‘Hd’, and the PMOS transistors MP0, MP1 transition from OFF to the boundary state accordingly. Moreover, the node ND2 becomes ‘H’, and accordingly the PMOS transistors MP2, MP3 transition from ON to OFF. Furthermore, the NMOS transistor MN10 transitions from OFF to ON (precisely, the boundary state) according to the inverted control signal (signal from the node ND5) and the NMOS transistor MN8 transitions from ON to OFF according to the control signal (signal from node ND6). As a result, such a state is constructed that is in a symmetric relation to FIG. 8B.

Supplementary description is given now about the NMOS transistors MN8, MN10. For example, in the upper part of FIG. 8C, in order for the NMOS transistor MN11 not to inhibit the raising operation of the inverted output node OUTB, the NMOS transistor MN10 may be OFF in the initial state, and the NMOS transistor MN11 may transition from ON to OFF in response to transition of the output signal (OUT) and then transition to ON. The NMOS transistor MN11 is turned ON to prepare for the transition of the input signal (INT) to ‘H’.

On the other hand, in order to validate the drop operation of the output node OUT to ‘L’ by the NMOS transistor MN9, the NMOS transistor MN8 may be ON in the initial state, and the NMOS transistor MN9 may transition from OFF to ON in response to transition of the inverted output signal (OUTB) and then transition to OFF after a predetermined period has passed. The NMOS transistor MN8 is turned OFF to prepare for the transition of the input signal (INT) to ‘Hl’. By using the inverted control signal (signal from the node ND5) and the control signal (signal from the node ND6) via the delay circuits DLY0, DLY1, it is possible to have the NMOS transistors MN8, MN10 perform such operations.

Contrary to “Time=0 to 10” in FIG. 8D, “Time=11 to 21” in FIG. 8E shows the transition state of the input node INT transitioning from ‘L’ to ‘Hl’. The transition state in FIG. 8E is a state in which one state is exchanged by the other state in a symmetric relation thereto shown in FIG. 8D, as in the prior embodiments. At the same time, the states of the nodes ND7, ND9 and the MOS transistors MN6, MN8, MN9 added or changed in this embodiment are exchanged by the state of the nodes ND8, ND10 and the NMOS transistors MN7, MN10, MN11, respectively.

### <<Major Effect of Seventh Embodiment>>

From the above, use of the level shift circuit according to the seventh embodiment makes it possible not only to obtain the effect similar to that in the sixth embodiment but also to further extend the power supply potential range in which the level shift operation can be performed, compared with the case in the inverted output node OUTB sixth embodiment. Specifically, for example, when the PMOS transistor MP2 raises the potential of the inverted output node OUTB, the NMOS transistor MN7 can be driven to be OFF. Consequently, the PMOS transistor MP2 can easily raise the potential of the inverted output node OUTB even if the input voltage amplitude further decreases according to the reduction of the internal power supply potential VDD1.

While the present invention made by the inventors are specifically described above with reference to various embodiments, the invention is not intended to be limited to the embodiments described above but may be modified without departing from the scope of the invention. For example, the embodiments are provided to comprehensively describe the invention in detail, but the invention is not limited to necessarily include all the configurations described above. Moreover, part of a configuration of one embodiment can be replaced by a configuration of another embodiment, and a configuration of one embodiment can be added to a configuration of another embodiment. Furthermore, part of a configuration of each embodiment can be added, deleted, or replaced by another configuration.

As an example, the level shift circuit may have a configuration as shown in FIG. 12. FIG. 12 is a circuit diagram showing a variation of the level shift circuit according to one embodiment of the invention. The level shift circuit shown in FIG. 12 includes a combination of the amplitude amplifying circuits AMPt3, AMPb3 shown in FIG. 4A and the sublevel shift circuit SLSC3 shown in FIG. 7A. In this manner, it is possible to combine the amplitude amplifying circuit and the sublevel shift circuit in various embodiments as desired. While the above embodiments use the MOS transistor as an example of the MISFET, the invention is not limited to the MISFET but it can be replaced by another transistor such as a bipolar transistor in some cases.

### ADDITIONAL STATEMENT

(1) A semiconductor device in each embodiment includes an internal logic circuit and a level shift circuit. The internal logic circuit is supplied with a reference power supply potential and a first power supply potential higher than the reference power supply potential to perform a predetermined processing, and outputs a signal with a first power supply voltage amplitude transitioning between the reference power supply potential and the first power supply potential. The level shift circuit is supplied with the reference power supply potential and a second power supply potential higher than the first power supply potential, and converts an input signal of the first power supply voltage amplitude from the internal logic circuit into an output signal of the second power supply voltage amplitude transitioning between the reference power supply potential and the second power supply potential. The level shift circuit includes an amplitude amplifying circuit that outputs a first signal of the first amplitude larger than the first power supply voltage amplitude and smaller than the second power supply voltage amplitude in response to the input signal of the first power supply voltage amplitude, and a sublevel shift circuit that outputs the output signal of the second power supply voltage amplitude in response to the first signal of the first amplitude.

What is claimed is:

1. A level shift circuit comprising:
an input node inputted with an input signal of a first power supply voltage amplitude transitioning between a reference power supply potential and a first power supply potential higher than the reference power supply potential;
an inverted input node inputted with an inverted input signal having a polarity opposite from that of the input signal;
an output node that outputs an output signal of a second power supply voltage amplitude transitioning between the reference power supply potential and a second power supply potential higher than the first power supply potential;
an inverted output node that outputs an inverted output signal having a polarity opposite from that of the output signal;
a zeroth A transistor of a first conductive type arranged between a first node and the reference power supply potential and driven by the input signal;
a zeroth B transistor of a second conductive type arranged between the second power supply potential and the first node;
a first A transistor of the first conductive type arranged between the output node and the reference power supply potential and driven by the inverted output signal;
a first B transistor of the second conductive type arranged between the second power supply potential and the output node and driven by a signal from the first node;
a third A transistor of the first conductive type arranged between a second node and the reference power supply potential and driven by the inverted input signal;
a third B transistor of the second conductive type arranged between the second power supply potential and the second node;
a second A transistor of the first conductive type arranged between the inverted output node and the reference power supply potential and driven by the output signal; and
a second B transistor of the second conductive type arranged between the second power supply potential and the inverted output node and driven by a signal from the second node,
wherein each of the zeroth B transistor and the third B transistor is driven to be ON by a voltage amplitude smaller than the second power supply voltage amplitude.

2. The level shift circuit according to claim 1,
wherein the zeroth B transistor is driven by a signal from the first node, and
wherein the third B transistor is driven by a signal from the second node.

3. The level shift circuit according to claim 1,
wherein each of the zeroth B transistor and the third B transistor is driven to be ON by a fixed potential set in advance.

4. The level shift circuit according to claim 1, further comprising:
a fourth A transistor arranged between the first node and the zeroth A transistor and driven to be ON according to transition of the inverted output signal to the second power supply potential or transition of the output signal to the reference power supply potential, and
a fifth A transistor arranged between the second node and the third A transistor and driven to be ON according to transition of the output signal to the second power supply potential or transition of the inverted output signal to the reference power supply potential.

5. The level shift circuit according to claim 4, further comprising:
a fourth B transistor of the second conductive type coupled in parallel with the first B transistor and driven by the inverted output signal, and
a fifth B transistor of the second conductive type coupled in parallel with the second B transistor and driven by the output signal.

6. The level shift circuit according to claim 5, further comprising:
a delay circuit that outputs a control signal generated by delaying the output signal and an inverted control signal having a polarity opposite from that of the control signal;
a sixth B transistor of the second conductive type coupled in parallel with the zeroth B transistor and driven by the inverted control signal, and
a seventh B transistor of the second conductive type coupled in parallel with the third B transistor and driven by the control signal.

7. The level shift circuit according to claim 6, further comprising:
a sixth A transistor of the first conductive type arranged between the first A transistor and the reference power supply potential; and
a seventh A transistor of the first conductive type arranged between the second A transistor and the reference power supply potential,
wherein, during a period in which the second B transistor makes the inverted output signal transition to the second power supply potential, the seventh A transistor is driven to be ON or OFF by a voltage amplitude smaller than the second power supply voltage amplitude and the sixth A transistor is driven to be ON, and
wherein, during a period in which the first B transistor makes the output signal transition to the second power supply potential, the sixth A transistor is driven to be ON or OFF by a voltage amplitude smaller than the second power supply voltage amplitude and the seventh A transistor is driven to be ON.

8. The level shift circuit according to claim 7,
wherein the seventh A transistor is driven by the second node, and
wherein the sixth A transistor is driven by the first node.

9. The level shift circuit according to claim 7,
wherein the seventh A transistor is driven by the input signal, and
wherein the sixth A transistor is driven by the inverted input signal.

10. The level shift circuit according to claim 9, further comprising:
an eleventh A transistor of the first conductive type arranged between the reference power supply potential and the inverted output node and driven by the output signal;
a ninth A transistor of the first conductive type arranged between the reference power supply potential and the output node and driven by the inverted output signal;
a tenth A transistor of the first conductive type arranged between the inverted output node and the eleventh A transistor and driven by the inverted control signal, and
an eighth A transistor of the first conductive type arranged between the output node and the ninth A transistor and driven by the control signal.

11. The level shift circuit according to claim 5, further comprising:
a sixth A transistor of the first conductive type arranged between the first A transistor and the reference power supply potential; and
a seventh A transistor of the first conductive type arranged between the second A transistor and the reference power supply potential,
wherein, during a period in which the second B transistor makes the inverted output signal transition to the second power supply potential, the seventh A transistor is driven to be ON or OFF by a voltage amplitude smaller than the second power supply voltage amplitude and the sixth A transistor is driven to be ON, and
wherein, during a period in which the first B transistor makes the output signal transition to the second power supply potential, the sixth A transistor is driven to be ON or OFF by a voltage amplitude smaller than the second power supply voltage amplitude and the seventh A transistor is driven to be ON.

12. A level shift circuit that is inputted with an input signal of a first power supply voltage amplitude transitioning between a reference power supply potential and a first power supply potential higher than the reference power supply potential and that outputs an output signal of a second power supply voltage amplitude transitioning between the reference power supply potential and a second power supply potential higher than the first power supply potential, the level shift circuit comprising:
an amplitude amplifying circuit that is supplied with the reference power supply potential and the second power supply potential and that outputs a first signal of a first amplitude larger than the first power supply voltage amplitude and smaller than the second power supply voltage amplitude in response to the input signal of the first power supply voltage amplitude, and
a sublevel shift circuit that is supplied with the reference power supply potential and the second power supply potential and that outputs the output signal of the second power supply voltage amplitude in response to the first signal of the first amplitude.

13. The level shift circuit according to claim 12,
wherein the amplitude amplifying circuit comprises:
a zeroth A transistor of a first conductive type arranged between a first node and the reference power supply potential and driven by the input signal, and
a load circuit that is arranged between the second power supply potential and the first node and that outputs to the first node the first signal of the first amplitude corresponding to a current in the zeroth A transistor.

14. The level shift circuit according to claim 13,
wherein the sublevel shift circuit comprises:
a first B transistor of a second conductive type arranged between the second power supply potential and the output node and driven by the first signal, and
a first A transistor of the first conductive type arranged between the output node and the reference power supply potential and driven by an inverted output signal having a polarity opposite from that of the output signal.

15. The level shift circuit according to claim 13,
wherein the amplitude amplifying circuit further comprises a switch arranged between the first node and the zeroth A transistor, driven to be ON according to transition of the output signal to the reference power supply potential, and driven to be OFF according to the transition to the second power supply potential.

16. The level shift circuit according to claim 15,
wherein the sublevel shift circuit further comprises a fourth B transistor of the second conductive type coupled in parallel with the first B transistor and driven by the inverted output signal.

17. The level shift circuit according to claim 14,
wherein the sublevel shift circuit further comprises a sixth A transistor of the first conductive type arranged between the first A transistor and the reference power supply potential, and
wherein, during a period in which the first B transistor makes the output signal transition to the second power supply potential, the sixth A transistor is driven to be ON or OFF by a voltage amplitude smaller than the second power supply voltage amplitude and driven to be ON during a period in which the inverted output signal transitions to the second power supply potential.

18. The level shift circuit according to claim 17,
wherein the sixth A transistor is driven by the first node.

19. The level shift circuit according to claim 13,
wherein the load circuit comprises a zeroth B transistor of a second conductive type.

20. A semiconductor device comprising:
an internal logic circuit that is supplied with a reference power supply potential and a first power supply potential higher than the reference power supply potential to perform a predetermined processing, and that outputs a signal with a first power supply voltage amplitude transitioning between the reference power supply potential and the first power supply potential; and
a level shift circuit that is supplied with the reference power supply potential and a second power supply potential higher than the first power supply potential, and that converts an input signal of the first power supply voltage amplitude from the internal logic circuit into an output signal of the second power supply voltage amplitude transitioning between the reference power supply potential and the second power supply potential,
wherein the level shift circuit comprises:
an input node inputted as the input signal;
an inverted input node inputted with an inverted input signal having a polarity opposite from that of the input signal;
an output node that outputs the output signal;
an inverted output node that outputs an inverted output signal having a polarity opposite from that of the output signal;
a zeroth A transistor of a first conductive type arranged between a first node and the reference power supply potential and driven by the input signal;
a zeroth B transistor of a second conductive type arranged between the second power supply potential and the first node;
a first A transistor of the first conductive type arranged between the output node and the reference power supply potential and driven by the inverted output signal;
a first B transistor of the second conductive type arranged between the second power supply potential and the output node and driven by a signal from the first node;
a third A transistor of the first conductive type arranged between a second node and the reference power supply potential and driven by the inverted input signal;
a third B transistor of the second conductive type arranged between the second power supply potential and the second node;
a second A transistor of the first conductive type arranged between the inverted output node and the reference power supply potential and driven by the output signal; and
a second B transistor of the second conductive type arranged between the second power supply potential and the inverted output node and driven by a signal from the second node,
wherein each of the zeroth B transistor and the third B transistor is driven to be ON by a voltage amplitude smaller than the second power supply voltage amplitude.
